(19) United States
(12) Patent Application Publication
(10) Pub. No.: US 2026/0366192 A1
(43) Pub. Date: Nov. 19, 2026

(54) GAS INTAKE LINER FOR VAPOR DEPOSITION PROCESS CHAMBER

(71) Applicant: BEIJING NAURA MICROELECTRONICS EQUIPMENT CO., LTD., Beijing (CN)

(72) Inventors: Xing KANG, Beijing (CN); Zhiwen ZHOU, Beijing (CN); Leilei WANG, Beijing (CN)

(21) Appl. No.: 19/664,005

(22) Filed: Apr. 30, 2026

Related U.S. Application Data
(63) Continuation of application No. PCT/CN2024/126662, filed on Oct. 23, 2024.

(30) Foreign Application Priority Data
Oct. 31, 2023 (CN) 202311437657.X
Oct. 31, 2023 (CN) 202322941863.6
Oct. 31, 2023 (CN) 202322944296.X
Oct. 31, 2023 (CN) 202322944310.6

(51) Int. Cl. C30B 25/14; C30B 25/08

(52) U.S. Cl. CPC C30B 25/14; C30B 25/08

(57) ABSTRACT

A gas intake liner for a vapor deposition process chamber, configured to connect with an intake port of an inner liner of the vapor deposition process chamber, the gas intake liner having a plurality of gas intake holes arranged in a first direction and isolated from each other, the plurality of gas intake holes having a same through direction, and the first direction being perpendicular to the through direction of the plurality of gas intake holes.

### CROSS-REFERENCE TO RELATED APPLICATION

This application is a continuation of International Application No. PCT/CN2024/126662, filed on Oct. 23, 2024, which claims priority to Chinese Patent Application No. CN202311437657.X, CN202322944310.6, CN202322944296.X, CN202322941863.6, filed on Oct. 31, 2023, incorporated herein by reference in their entirety.

### TECHNICAL FIELD

The present disclosure generally relates to the field of semiconductor process equipment technology and, more particularly, to a gas intake liner for a vapor deposition process chamber.

### BACKGROUND

Vapor deposition processes typically occur in vapor deposition process chambers within semiconductor process equipment. Vapor deposition is a process for growing thin films (e.g., silicon-based thin films) on wafers. To ensure process effectiveness, during vapor deposition, it is needed to ensure that a relatively uniform process environment is formed in the vicinity of the wafer or to minimize the adverse effects of process gases on the components inside the vapor deposition process chamber.

However, the vapor deposition process chambers in related technologies are difficult to implement. Specifically, the vapor deposition process chambers in related technologies suffer from poor process quality, high maintenance costs, and low throughput.

### SUMMARY

The present disclosure discloses a gas intake liner for a vapor deposition process chamber, configured to connect with an intake port of an inner liner of the vapor deposition process chamber, the gas intake liner having a plurality of gas intake holes arranged in a first direction and isolated from each other, the plurality of gas intake holes having a same through direction, and the first direction being perpendicular to the through direction of the plurality of gas intake holes.

### BRIEF DESCRIPTION OF THE DRAWINGS

FIG. 1 is a cross-sectional view of the vapor deposition process chamber disclosed in an embodiment of the present disclosure;

FIG. 2 is a cross-sectional view of the vapor deposition process chamber disclosed in an embodiment of the present disclosure;

FIG. 3 is an enlarged view of a part of the structure in FIG. 1;

FIG. 4 is an enlarged view of a part of the structure in FIG. 3;

FIG. 5 is a structural schematic diagram of the upper liner ring disclosed in an embodiment of the present disclosure;

FIG. 6 is a cross-sectional view along line A-A in FIG. 5;

FIG. 7 is a three-dimensional structural schematic diagram of the upper liner ring disclosed in an embodiment of the present disclosure;

FIG. 8 is a structural schematic diagram of one type of first guide and second guide disclosed in an embodiment of the present disclosure;

FIG. 9 is a structural schematic diagram of the lower liner ring disclosed in an embodiment of the present disclosure.

FIG. 10 is a cross-sectional view along line B-B of FIG. 9;

FIG. 11 is a three-dimensional structural schematic diagram of the lower liner ring disclosed in an embodiment of the present disclosure;

FIG. 12 is a cross-sectional view of the inner liner disclosed in an embodiment of the present disclosure;

FIG. 13 is a cross-sectional view of the inner liner and the gas intake liner after assembly, as disclosed in an embodiment of the present disclosure;

FIG. 14 is a cross-sectional view of the inner liner and the gas intake liner after assembly, as disclosed in an embodiment of the present disclosure, from another perspective;

FIG. 15 is an exploded schematic diagram of the inner liner disclosed in an embodiment of the present disclosure;

FIG. 16 is an exploded schematic diagram of the inner liner and the gas intake liner disclosed in an embodiment of the present disclosure;

FIGS. 17 and 18 are respectively a split structure and an integral structure of the gas intake liner;

FIG. 19A is a schematic diagram of the flow field of the process gas, assuming the distance between the first guide and the second guide is constant;

FIG. 19B is a partially enlarged view of FIG. 19A;

FIG. 20 schematically shows the process gas flow field when the distance between the first guide and second guide gradually decreases;

FIG. 21 is a partially enlarged view of FIG. 20;

FIGS. 22 and 23 schematically show the process gas flow field when the ratios of the first distance to the second distance are 1.2 and 1.4, respectively;

FIGS. 24 and 25 schematically show the process gas flow field when the ratios of the inner diameter of the inner liner to the diameter of the circle containing the arc-shaped guide section are 0.6 and 0.8, respectively;

FIG. 26 schematically shows the protective gas flow field when the ratio of the first area to the second area is greater than 600;

FIG. 27 schematically shows the protective gas flow field when the ratio of the first area to the second area is less than 600;

FIG. 28 is a schematic diagram of the structure of the gas intake seat disclosed in an embodiment of the present disclosure;

FIG. 29 is a cross-sectional view along the line C-C of FIG. 28;

FIG. 30 is a schematic diagram of the structure of the vapor deposition process chamber disclosed in an embodiment of the present disclosure;

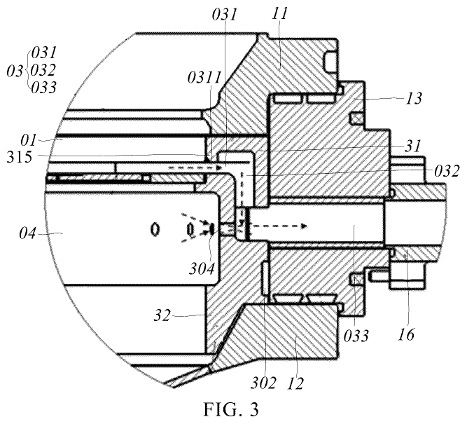

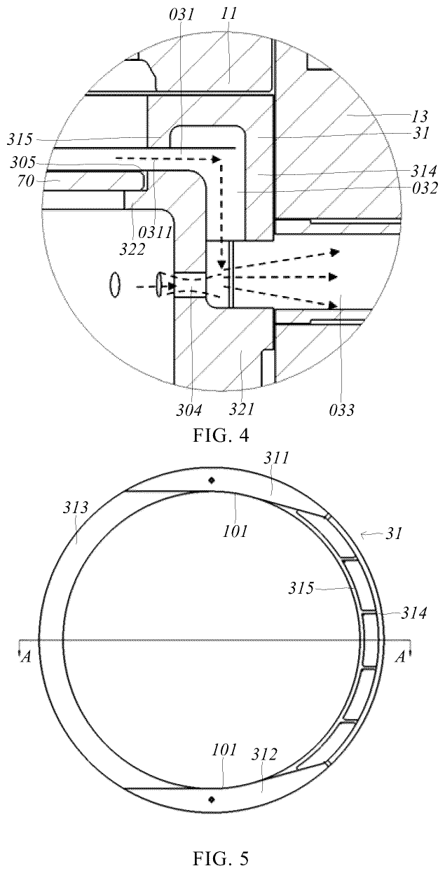

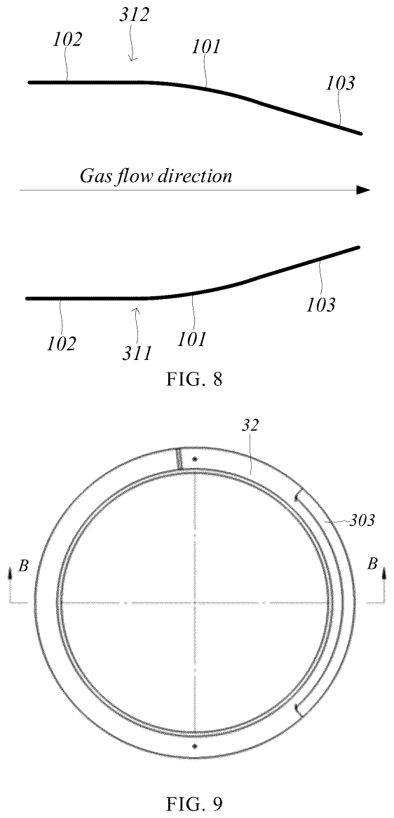

The arrows in FIGS. 3, 4, 7, 8, 11, and 30 indicate the flow direction of the gas (process gas or driving gas).

### REFERENCE NUMERALS

10-Chamber, 11-Top cover, 111-Chamber top wall, 12-Bottom cover, 13-Base ring, 14-Gas intake seat, 141-Gas input passage, 15-Gas intake pipe, 16-Gas exhaust seat,
20-Carrier, 21-Carrying surface,
30-Inner liner, 31-Upper liner ring, 311-First guide, 312-Second guide, 313-First ring body, 314-Baffle, 315-Protrusion, 32-Lower liner ring, 321-Second ring body, 322-Annular flange, 33-Gas intake liner, 331-First assembly, 332-First spacer, 333-Second assembly, 334-Second spacer,
301-Intake notch, 302-Annular groove, 303-Recess, 304-Gas delivery hole, 305-Annular positioning groove, 306-Transfer port, 307-Gas intake hole, 308-Top flat wall, 309-Bottom flat wall, 310-Arc-shaped sidewall,
101-Arc-shaped guide section, 102-First straight guide section, 103-Second straight guide section,
01-Process space, 02-Intake passage, 021-Intake port, 03-Exhaust passage, 031-First exhaust section, 0311-Exhaust port, 032-Second exhaust section, 033-Third exhaust section, 04-Driving gas chamber, 05-Chamber space,
40-Upper heating module, 41-First outer zone heating lamp, 42-First inner zone heating lamp, 43-First reflector, 44-Second reflector,
50-Lower heating module, 51-Second outer zone heating lamp, 52-Second inner zone heating lamp, 53-Third reflector, 54-Fourth reflector,
60-Wafer, 70-Preheating ring.

### DETAILED DESCRIPTION OF THE EMBODIMENTS

To make the objectives, technical solutions, and advantages of the present disclosure clearer, the technical solutions of the present disclosure will be described below in conjunction with specific embodiments and corresponding drawings. Obviously, the described embodiments are only a part of the embodiments of the present disclosure, and not all of them. Based on the embodiments in the present disclosure, all other embodiments obtained by those skilled in the art without creative effort are within the scope of the present disclosure.

The vapor deposition process chamber involved in the related technology has many problems, specifically manifested in the following aspects.

In a first aspect, after the process gas enters the process space of the vapor deposition process chamber, the process gas flows towards the exhaust passage. As the process proceeds and the process gas is gradually consumed, the concentration of the process gas near the exhaust passage is low, resulting in a thinner film deposited on the wafer in the area near the exhaust passage. Ultimately, this leads to uneven film thickness on the wafer, which undoubtedly results in poor process quality.

In a second aspect, during the vapor deposition process, process gases can seep into the assembly gaps of the vapor deposition chamber, leading to defective deposition. This results in more difficult and costly subsequent cleaning of components with defective deposition, ultimately leading to higher maintenance costs and lower production capacity for the vapor deposition chamber.

To address these issues, embodiments of the present disclosure disclose an upper liner ring, a lower liner ring, a gas intake liner, and an inner liner for a vapor deposition chamber. Furthermore, embodiments of the present disclosure disclose a vapor deposition chamber including at least one of the upper liner ring, lower liner ring, and gas intake liner, as well as a vapor deposition chamber including an inner liner and semiconductor process equipment including the vapor deposition chamber. Correspondingly, the disclosed vapor deposition chamber and semiconductor process equipment can also solve the technical problems existing in the related art.

The following detailed description, with reference to the accompanying drawings, describes the upper liner ring, lower liner ring, inner liner, and gas intake liner of the vapor deposition process chamber disclosed in the present disclosure, as well as the vapor deposition process chamber and semiconductor process equipment.

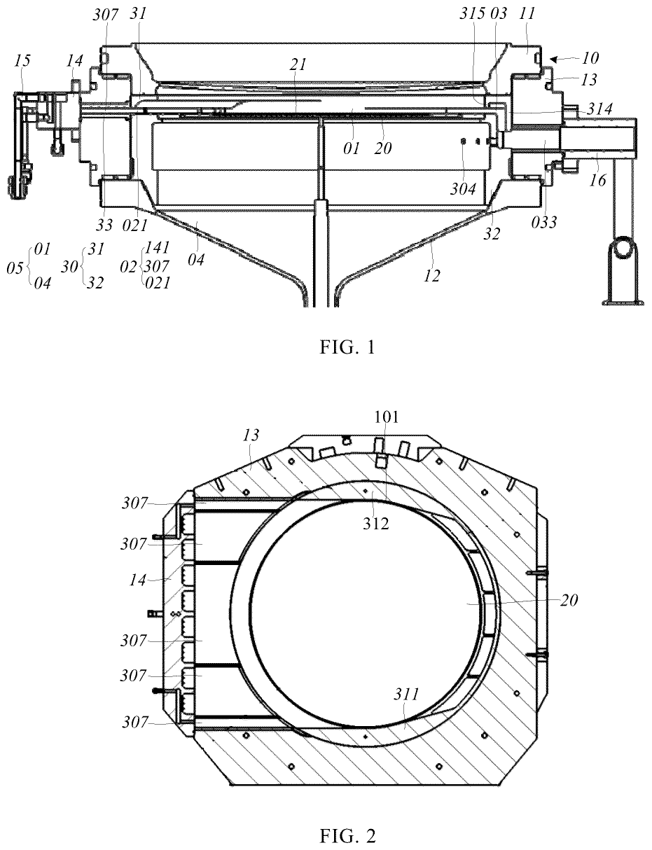

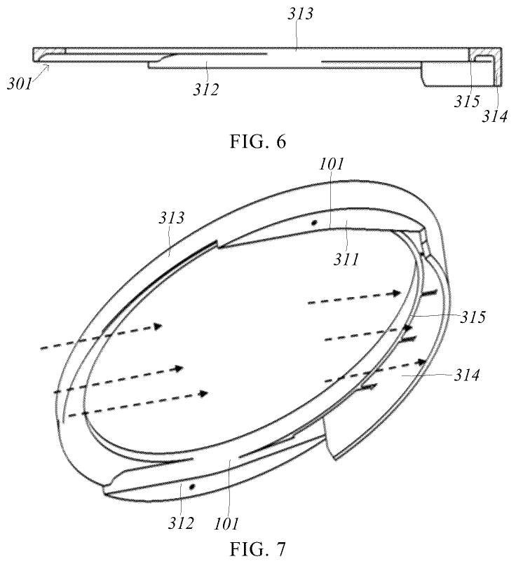

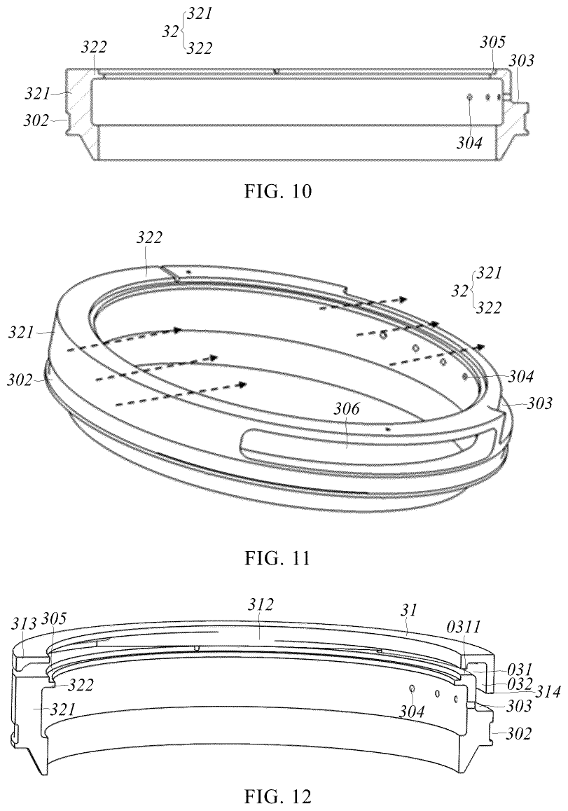

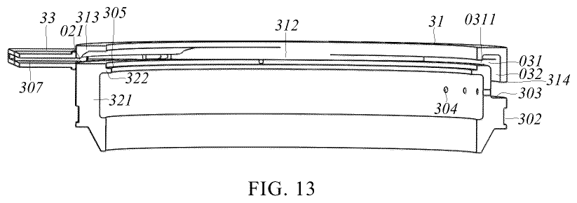

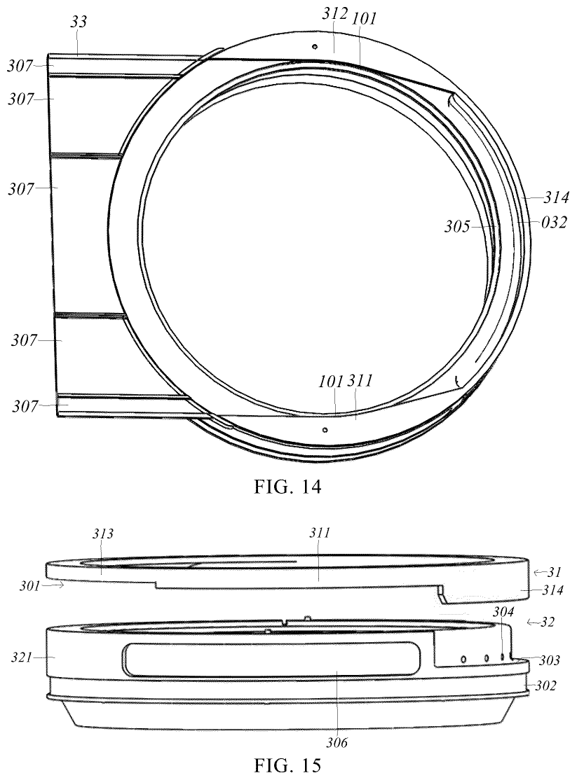

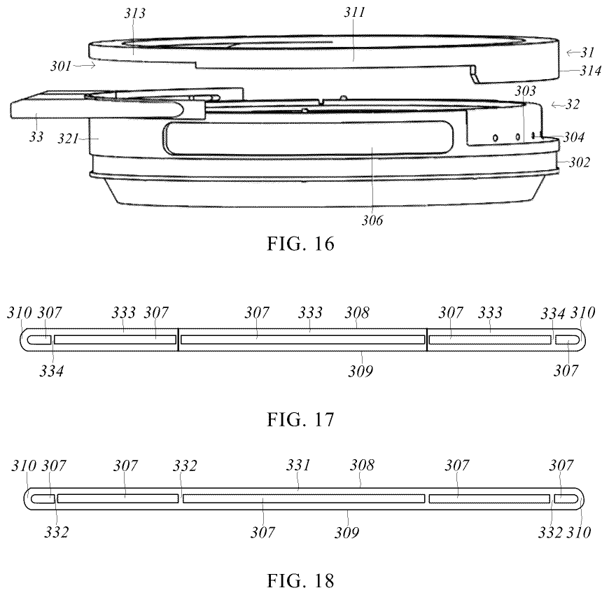

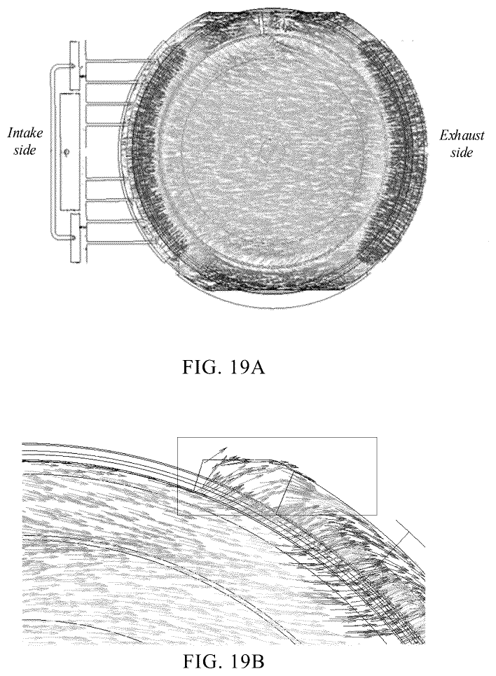

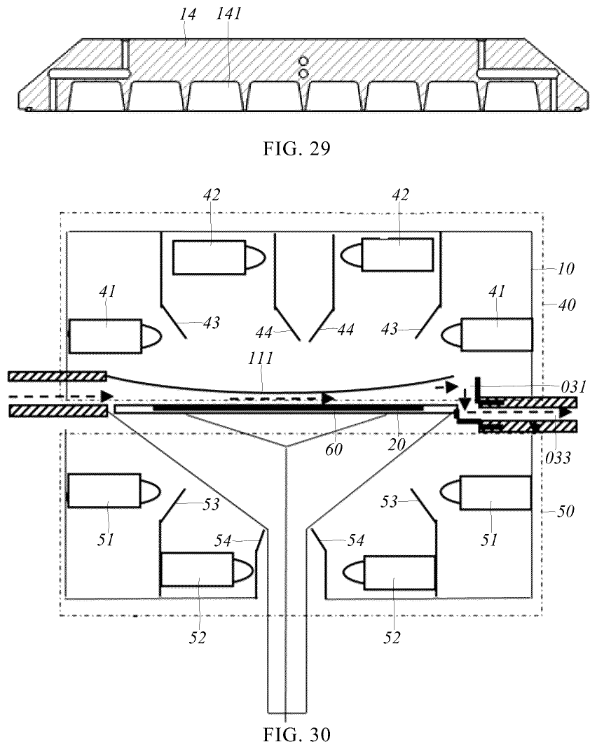

As shown in FIGS. 1 to 30, the vapor deposition process chamber disclosed in the present disclosure includes at least a chamber 10, a carrier 20, and an inner liner 30.

The vapor deposition process chamber has a process space 01, an intake passage 02, and an exhaust passage 03. The process space 01 is the space where the vapor deposition process takes place. The intake passage 02 and the exhaust passage 03 are located at opposite sides of the process space 01 and are respectively connected to the process space 01. The intake passage 02 is configured to input process gas into the process space 01, and the waste gas formed after the process gas participates in the vapor deposition process within the process space 01 will be discharged outside the process space 01 through the exhaust passage 03. Specifically, the waste gas can be discharged outside the vapor deposition process chamber through the exhaust passage 03, and then treated by subsequent waste gas treatment processes.

Chamber 10 is the main peripheral component of the vapor deposition process chamber. Chamber 10 can form process space 01 together with other components of the vapor deposition process chamber (e.g., inner liner 30). Of course, process space 01 can also be formed by other components of the vapor deposition process chamber (e.g., inner liner 30), and the present disclosure does not impose any limitations.

A carrier 20 is disposed within chamber 10. Carrier 20 is configured to carry wafer 60. Specifically, carrier 20 has a carrying surface 21 directly carrying wafer 60 for vapor deposition. The present disclosure does not limit the specific shape of carrying surface 21, as long as carrying surface 21 can stably carry wafer 60 for vapor deposition.

Inner liner 30 is disposed within chamber 10. Specifically, the inner liner 30 can be fixed within the chamber 10 to ensure stable installation within the chamber 10. The inner liner 30 at least serves to protect other components of the vapor deposition process chamber (e.g., the chamber 10). For easy disassembly and replacement or subsequent cleaning, the inner liner 30 can be detachably connected within the chamber 10. In the present disclosure, the inner liner 30 can be an integral structure (i.e., manufactured using a one-piece molding process) or a split structure; the present disclosure is not limited thereto.

In some embodiments, the inner liner 30 may include a first guide 311 and a second guide 312. Both the first guide 311 and the second guide 312 function as guide. The first guide 311 and the second guide 312 are arranged opposite to each other, and a guide passage is formed between the first guide 311 and the second guide 312. The guide passage is located within the process space 01. The two ends of the guide passage are connected to the intake passage 02 and the exhaust passage 03, respectively. The process gas entering the process space 01 through the intake passage 02 flows towards the exhaust passage 03 during vapor deposition. During this process, the guide passage guides the flow of the process gas. The first guide 311 and the second guide 312 are arranged opposite each other, for example, in a horizontal direction perpendicular to the direction from the intake passage 02 to the exhaust passage 03.

In the present disclosure, the inner liner 30 also includes, for example, an annular liner, the annular liner is the annular part of the inner liner 30. The annular liner surrounds the carrier 20. The process space 01 is formed by at least the carrier 20 and the annular liner. The first guide 311 and the second guide 312 are disposed at the annular liner. The distance between the first end of the first guide 311 and the first end of the second guide 312 is a first distance. The distance between the second end of the first guide 311 and the second end of the second guide 312 is a second distance. The first distance is greater than the second distance. The first distance and the second distance are, for example, distances in the aforementioned horizontal direction perpendicular to the direction from the intake passage 02 to the exhaust passage 03.

The first end of the first guide 311 and the first end of the second guide 312 are respectively the ends of the first guide 311 and the second guide 312 closest to the intake passage 02. The second end of the first guide 311 and the second end of the second guide 312 are respectively the other ends of the first guide 311 and the second guide 312 closest to the exhaust passage 03. The first end and the second end of the first guide 311 are the two ends opposite to each other. The first end and the second end of the second guide 312 are the two ends opposite to each other.

Furthermore, in the present disclosure, the direction from the intake passage 02 to the exhaust passage 03 is the gas flow direction. Of course, as described above, the process gas enters the guide passage formed by the first guide 311 and the second guide 312 after being input through the intake passage 02, and is finally discharged through the guide passage to the exhaust passage 03. This means that the inner liner 30 itself has an intake side and an exhaust side, and the intake side and the exhaust side are opposite sides of the inner liner 30. The intake side of the inner liner 30 is connected to the intake passage 02 of the vapor deposition process chamber, and the exhaust side of the inner liner 30 is connected to the exhaust passage 03 of the vapor deposition process chamber. The direction from the intake side of the inner liner 30 to the exhaust side of the inner liner 30 can also be considered as the gas flow direction. The first guide 311 and the second guide 312 are located between the intake side and the exhaust side of the inner liner 30. The first end of the first guide 311 and the first end of the second guide 312 are both located at the intake side of the inner liner 30, and the second end of the first guide 311 and the second end of the second guide 312 are both located at the exhaust side of the inner liner 30.

The technical solution disclosed in the present disclosure involves a structural design of the inner liner 30, such that the inner liner 30 includes opposing first guide 311 and second guide 312, and the distance between the first end of the first guide 311 and the first end of the second guide 312 (i.e., a first distance) is greater than the distance between the second end of the first guide 311 and the second end of the second guide 312 (i.e., a second distance). This structure allows the first guide 311 and the second guide 312 to guide the flow, thereby confining the process gas within a narrower area on the exhaust side of the inner liner 30. During this process, as the process gas is consumed, the concentration of the process gas decreases. However, due to the action of the first guide 311 and the second guide 312, the lower concentration of the process gas is confined to a narrower region, thus increasing the concentration of the process gas within that narrower region. This method is beneficial for increasing the concentration of the process gas in the region adjacent to the exhaust passage 03 within the process space 01, thereby ensuring the film thickness on the wafer 60 in this region, and ultimately contributing to a more uniform film thickness across all regions of the wafer 60.

The concentration of the process gas mentioned herein refers to the amount of process gas per unit space. Since the distance between the second end of the first guide 311 and the second end of the second guide 312 is small, the corresponding region is smaller, which is beneficial for increasing the amount of process gas per unit space.

As mentioned above, the distance between the first ends of the first guide 311 and the first ends of the second guide 312 is greater than the distance between the second ends of the first guide 311 and the second guide 312. Various structures can achieve this difference in distance. Specifically, in the gas flow direction (i.e., from the intake side to the exhaust side of the inner liner 30), the distance between the first guide 311 and the second guide 312 can vary with a large gradient. For example, the opposing inner edges of the first guide 311 and the second guide 312 are both stepped edges.

Of course, in order to achieve better guidance of the process gas and reduce the probability of disturbance of the process gas during flow, in some embodiments, the distance between the first guide 311 and the second guide 312 can gradually decrease in the direction from the intake side to the exhaust side of the inner liner 30. This allows the opposing inner edges of the first guide 311 and the second guide 312 to change in a smoother manner, so that the process gas is gradually guided to a narrower area after entering the guide passage between the first guide 311 and the second guide 312. This facilitates laminar flow of the process gas and alleviates turbulence. The laminar flow of process gas helps ensure the uniformity of the process gas within the process space 01, which in turn improves the consistency of the film thickness deposited on wafer 60, ultimately enhancing the deposition performance.

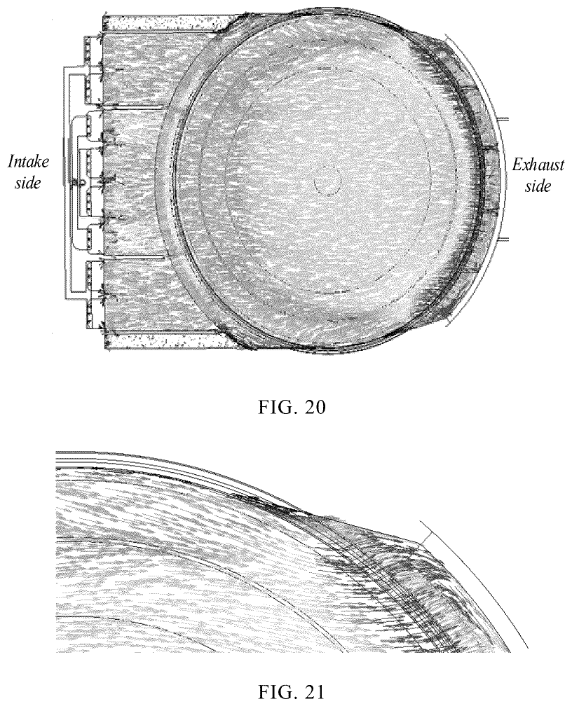

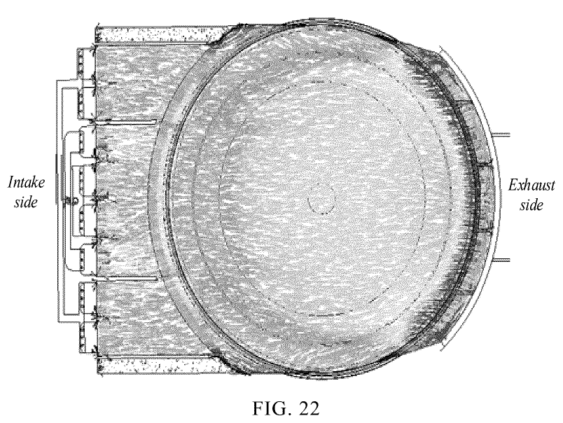

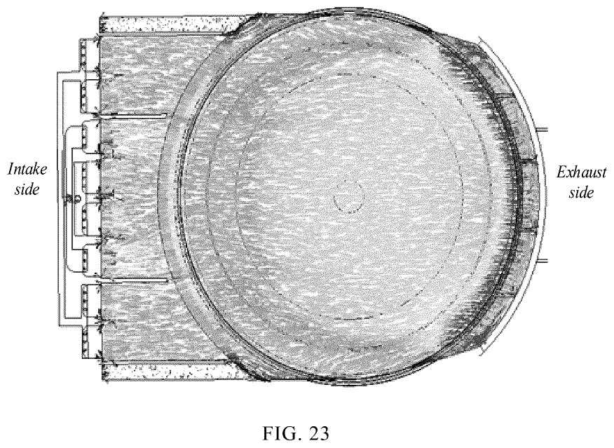

Simulations of the process gas flow field are shown in FIGS. 19A to 21. FIG. 19A schematically shows the process gas flow field assuming the distance between the first guide 311 and the second guide 312 is equal everywhere. FIG. 19B is a partially enlarged view of FIG. 19A. The flow field diagram within the box in FIG. 19B shows that turbulence is more severe near the exhaust side. FIGS. 20 and 21 schematically show the flow field as the distance between the first guide 311 and the second guide 312 gradually decreases from the intake side to the exhaust side. FIGS. 20 and 21 show that there is no turbulence during process gas flow.

In some embodiments, the ratio of the first distance to the inner diameter of the inner liner 30 can be greater than 1. The ratio of the second distance to the inner diameter of the inner liner 30 can be less than 1. In this configuration, a larger first distance allows for a more gradual decrease in the distance between the first guide 311 and the second guide 312, making it less likely to affect the carrier 20 and the wafer 60 placed on carrier 20. In the present disclosure, neither the first guide 311 nor the second guide 312 is located directly above the wafer 60 to avoid interfering with thin film deposition.

In some embodiments, the ratio of the difference between the first distance and the second distance to the inner diameter of the inner liner 30 can be greater than or equal to ⅙ and less than or equal to ⅓. In the present disclosure, the inner liner 30 is an annular structure, and the inner diameter of the inner liner 30 refers to the diameter of the circular inner wall of the inner liner 30. Similarly, the inner diameters of other components (such as the upper liner ring 31 and lower liner ring 32 described later) refer to the diameter of the corresponding circular inner wall. In the present disclosure, the inner diameter of the inner liner 30 is equal to the inner diameters of the upper liner ring 31 and the lower liner ring 32 mentioned later, and also equal to the inner diameter of the annular liner. In some embodiments, the circular inner wall of the inner liner 30, the circular inner walls of the upper liner ring 31, the lower liner ring 32, and the annular liner (mentioned later) are all circular inner walls of the same diameter, and the projections of the circular inner wall of the inner liner 30, the circular inner walls of the upper liner ring 31, the lower liner ring 32, and the annular liner in the direction perpendicular to the carrying surface 21 of the carrier 20 coincide, all forming the first circular region described later.

When the ratio of the first distance to the inner diameter of the inner liner 30 is greater than 1, the ratio of the second distance to the inner diameter of the inner liner 30 is less than 1, and the ratio of the difference between the first distance and the second distance to the inner diameter of the inner liner 30 is greater than or equal to ⅙ and less than or equal to ⅓, the flow field of the process gas is shown in FIGS. 20 and 21. FIGS. 20 and 21 show that there is no turbulence in the process gas.

Further, in the present disclosure, the ratio of the first distance to the second distance can be 1.2 to 1.4. Experiments have shown that when the ratio of the first distance to the second distance is within this range, the flow of process gas in the process space is relatively stable, and turbulence can be effectively mitigated. FIG. 22 schematically shows the process gas flow field when the ratio of the first distance to the second distance is 1.2, and FIG. 23 schematically shows the process gas flow field when the ratio of the first distance to the second distance is 1.4. Compared to FIGS. 19A and 19B, the process gas does not exhibit turbulence in the flow fields shown in FIGS. 22 and 23.

In the present disclosure, the ratio of the distance between the first guide 311 and the second guide 312 in the direction perpendicular to the first axis to the inner diameter of the inner liner 30 is 0.5 to 1.6. Further, in some embodiments, the ratio of the distance between the first guide 311 and the second guide 312 in a direction perpendicular to the first axis to the inner diameter of the inner liner 30 is 0.75 to 1.25, where the first axis is the central axis extending from the intake side to the exhaust side of the inner liner 30.

As mentioned above, the inner liner 30 can be a split structure. In this case, the first guide 311 and the second guide 312 can be integrally integrated into the constituent components of the inner liner 30 (e.g., the upper liner ring 31, lower liner ring 32, etc., described later), i.e., formed by a one-piece molding process. This method can reduce assembly gaps and assembly operations between components. Of course, the first guide 311 and the second guide 312 can also be a separate structure from other parts of the inner liner 30 and installed through assembly; the present disclosure does not impose any limitations.

In the present disclosure, the first guide 311 and the second guide 312 can be made of quartz, and the inner liner 30 can also be made of quartz. Of course, the present disclosure does not limit the specific materials of the first guide 311, the second guide 312, and the entire inner liner 30; any material that meets the requirements of the vapor deposition process chamber is acceptable.

To ensure that the gas field environment within the process space 01 is as consistent as possible, the inner liner 30 can have a symmetrical structure. Specifically, the inner liner 30 can have a symmetrical structure with the first axis as the axis of symmetry. Similarly, the first guide 311 and the second guide 312 can be symmetrically distributed with the first axis as the axis of symmetry. In this case, the first guide 311 and the second guide 312 can achieve relatively balanced guidance and relatively balanced confinement of the process gas in the region adjacent to the exhaust passage 03. Consistent with the present disclosure, the first axis is the central axis extending from the intake side of the inner liner 30 to the exhaust side of the inner liner 30.

In the present disclosure, the first guide 311 and the second guide 312 can be straight structural members parallel to the first axis, or curved structural members that are bent as a whole. Of course, the first guide 311 and the second guide 312 can also be structural members that are partly straight and partly curved. The present disclosure does not impose any limitations. As long as the first guide 311 and the second guide 312 do not occupy the space directly above the carrier 20 and do not affect the deposition of thin film on the wafer 60 on the carrier 20. As such, in some embodiments, the opposing inner edges of the first guide 311 and the second guide 312 can each include an arc-shaped guide section 101 protruding away from each other. The arc-shaped guide section 101 is not located directly above the carrier 20, thus avoiding the direct top of the carrier 20 and the wafer 60. The arc-shaped guide section 101 extends relatively smoothly, thereby better guiding the process gas and further facilitating the laminar flow of the process gas. It is important to emphasize that, in the present disclosure, laminar flow refers to the flow of process gas in a direction parallel to the carrying surface 21 of the carrier 20.

In some embodiments, the arc-shaped guide section 101 may be circumferentially tangent to the first circular region. The first circular region is the area enclosed by the projection of the circular inner wall of the inner liner 30 in a direction perpendicular to the carrying surface 21. The arc-shaped guide section 101 can be considered circumferentially tangent to the circular inner wall of the inner liner 30. This structure allows the first guide 311 and the second guide 312 to be as close as possible to the carrier 20 and the wafer 60 without being directly above the carrier 20 and the wafer 60, thereby effectively guiding and confining the process gas. In the present disclosure, the center of the circle containing the arc-shaped guide section 101 may be located within a circular region with a radius of 40 mm centered at the center of the first circular region. In the present disclosure, the circular inner wall of the inner liner 30 is the same as the circular inner wall of the upper liner ring 31 (the same as the circular inner wall of the first ring body 313 described later) described later, and also the same as the circular inner wall of the lower liner ring 32 (the same as the circular inner wall of the second ring body 321 described later) described later.

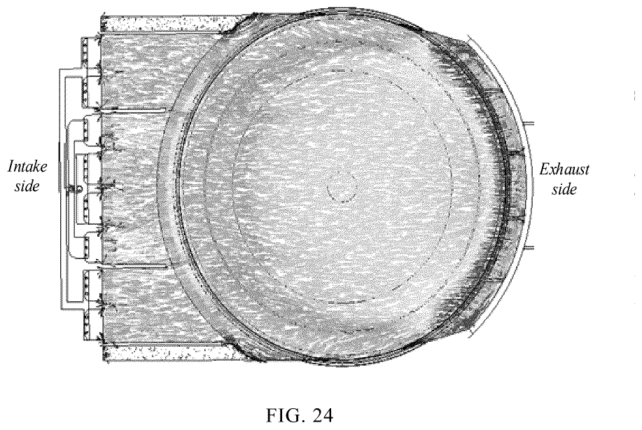

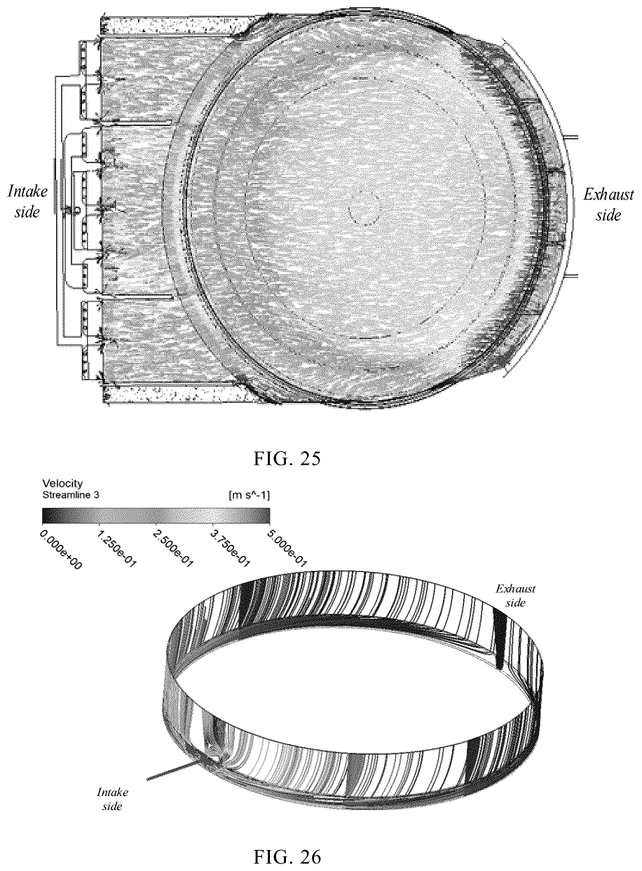

The present disclosure does not limit the size of the arc-shaped guide section 101. In some embodiments, the ratio of the inner diameter of the inner liner 30 to the diameter of the arc-shaped guide section 101 (i.e., the diameter of the circle containing the arc-shaped guide section 101) can be greater than or equal to 0.6 and less than or equal to 0.8. As shown in FIG. 24, when the ratio of the inner diameter of the inner liner 30 to the diameter of the circle containing the arc-shaped guide section 101 is 0.6, the process gas flow is relatively smooth, and turbulence is significantly reduced. As shown in FIG. 25, when the ratio of the inner diameter of the inner liner 30 to the diameter of the arc-shaped guide section 101 is 0.8, the process gas flow is relatively smooth, and turbulence is significantly reduced. It should be noted that, compared with FIG. 19, and the process gas shown in FIGS. 24 and 25 does not exhibit turbulence.

Furthermore, in some embodiments, the opposing inner edges of the first guide 311 and the second guide 312 may each include a first straight guide section 102 and a second straight guide section 103. The first straight guide section 102 and the second straight guide section 103 are respectively connected to the two ends of the corresponding arc-shaped guide section 101 and extend in directions away from each other. In this structure, both the first straight guide section 102 and the second straight guide section 103 are tangent to the circular inner wall of the inner liner 30 (i.e., the circular inner wall of the first annular body 313, the circular inner wall of the second annular body 321, and the circular inner wall of the annular liner). Since the first straight guide section 102 and the second straight guide section 103 are further away from the circular inner wall of the inner liner 30 than the arc-shaped guide section 101, it is unnecessary to design both the first guide 311 and the second guide 312 as arc-shaped structures to avoid the space above the carrier 20, the wafer 60, and the space directly above the carrier 20 and the wafer 60. Furthermore, the simple structure of the first straight guide section 102 and the second straight guide section 103 allows for more precise directional guidance, ultimately improving the guiding effect. It also makes it easier to design the magnitude of the first distance and the second distance.

The inner liner 30 disclosed in the present disclosure may include only the upper liner ring 31, only the lower liner ring 32, or both the upper liner ring 31 and the lower liner ring 32; the present disclosure is not limited in this regard. Correspondingly, the first guide 311 and the second guide 312 may be included in the upper liner ring 31 as part of the upper liner ring 31, and the first guide 311 and the second guide 312 may also be included in the lower liner ring 32 as part of the lower liner ring 32; the present disclosure is not limited in this regard.

As described above, in the present disclosure, the inner liner 30 may include an annular liner surrounding the carrier 20. When the inner liner 30 includes an upper liner ring 31 and a lower liner ring 32, the annular liner includes the part of the upper liner ring 31 surrounding the carrier 20 (as described later as the first ring body 313) and the part of the lower liner ring 32 surrounding the carrier 20 (as described later as the second ring body 321). An upper liner ring 31 is positioned above and coaxially arranged with the lower liner ring 32. At least the carrier 20, the upper liner ring 31, and the lower liner ring 32 can enclose a process space 01. An intake port 021 for the inner liner 30 is formed between the first end of the upper liner ring 31 and the first end of the lower liner ring 32, and the intake passage 02 includes the intake port 021. An exhaust port 0311 for the inner liner 30 is formed between the second end of the upper liner ring 31 and the second end of the lower liner ring 32; that is, an exhaust port 0311 is formed between the ends of the upper liner ring 31 and the lower liner ring 32 located at the exhaust side of the inner liner 30, and the exhaust passage 03 includes the exhaust port 0311. Of course, the side where the intake port 021 of the inner liner 30 is located is the intake side of the inner liner 30, which is also the intake side of the upper liner ring 31 and the lower liner ring 32. Similarly, the side where the exhaust port 0311 of the inner liner 30 is located is the exhaust side of the inner liner 30, which is also the exhaust side of the upper liner ring 31 and the lower liner ring 32.

It needs to be emphasized again that, in the present disclosure, the intake side of the upper liner ring 31 and the intake side of the lower liner ring 32 are the same as the intake side of the inner liner 30. At least one of the upper liner ring 31 or the lower liner ring 32 has a structure capable of gas intake. The exhaust side of the upper liner ring 31 and the exhaust side of the lower liner ring 32 are the same as the exhaust side of the inner liner 30. At least one of the upper liner ring 31 or the lower liner ring 32 has a structure capable of gas exhaust. The directions from the intake side to the exhaust side of the upper liner ring 31, from the intake side to the exhaust side of the lower liner ring 32, and from the intake side to the exhaust side of the inner liner 30 are all consistent and represent the gas flow direction described in the present disclosure.

Furthermore, the first axis mentioned above is the central axis of the inner liner 30 extending along the gas flow direction, as well as the central axis of the upper liner ring 31 extending along the gas flow direction, and also the central axis of the lower liner ring 32 extending along the gas flow direction. In other words, when the inner liner 30, upper liner ring 31, and lower liner ring 32 are all symmetrical structures, the axes of the inner liner 30 extending along the gas flow direction, the upper liner ring 31, and the lower liner ring 32 are all the first axis, and the inner liner 30, upper liner ring 31, and lower liner ring 32 are all symmetrical structures with the first axis as the axis of symmetry.

As mentioned above, the distance between the first guide 311 and the second guide 312 can gradually decrease. In the specific design process, the magnitude of the reduction in distance between the first guide 311 and the second guide 312 can be equal or unequal. In some embodiments, the reduction in distance between the section of the first guide 311 located at the intake side of the inner liner 30 and the section of the second guide 312 located at the intake side of the inner liner 30 can be a first distance reduction, and the reduction in distance between the section of the first guide 311 located at the exhaust side of the inner liner 30 and the section of the second guide 312 located at the exhaust side of the inner liner 30 can be a second distance reduction. The first distance reduction can be less than the second distance reduction. This design allows the guidance of the first guide 311 and the second guide 312 to be more targeted. Since the process gas consumption is less in the area near the intake side of the inner liner 30, the reduction in process gas concentration is not significant. Therefore, reducing the distance between the first guide 311 and the second guide 312 slightly without excessive reduction helps to minimize the impact on the flow of process gas. The process gas consumption is higher and concentration of the process gas decreases more significantly in the region near the exhaust side of the inner liner 30. Here, the distance between the first guide 311 and the second guide 312 is significantly reduced, facilitating the timely and rapid converging of process gas within a narrower region to achieve a higher efficiency in increasing the process gas concentration. This, in turn, ensures the deposition efficiency and effect of the wafer 60 in the region adjacent to the exhaust passage 03.

As the embodiments described above, the opposing inner edges of the first guide 311 and the second guide 312 may further include a first straight guide section 102 and a second straight guide section 103. The first straight guide section 102 is located at the intake side of the inner liner 30, and the second straight guide section 103 is located at the exhaust side of the inner liner 30. Based on the present disclosure, a more specific structure can be formed based on the design concept of unequal distance reduction, as follows: both the first straight guide section 102 and the second straight guide section 103 are inclined relative to the first axis. The angle between the first straight guide section 102 and the first axis is smaller than the angle between the second straight guide section 103 and the first axis. In this case, the inclination of the first straight guide section 102 relative to the first axis is smaller, resulting in a smaller reduction in the distance between the first straight guide section 102 of the first guide 311 and the first straight guide section 102 of the second guide 312. The inclination of the second straight guide section 103 relative to the first axis is larger, resulting in a larger reduction in the distance between the second straight guide section 103 of the first guide 311 and the second straight guide section 103 of the second guide 312.

The present disclosure does not limit the angle between the first straight guide section 102 and the first axis, nor the angle between the second straight guide section 103 and the first axis. In some embodiments, the angle between the first straight guide section 102 and the first axis can be 3° to 10°, and the angle between the second straight guide section 103 and the first axis can be 10° to 20°.

As described above, an intake port 021 of the inner liner 30 is formed between the first end of the upper liner ring 31 and the first end of the lower liner ring 32. There are various structures for forming the intake port 021. To facilitate the formation of the intake port 021, in some embodiments, an intake notch 301 can be formed at the intake side of the upper liner ring 31. The design of the intake notch 301 makes it easier to form the intake port 021 at the intake side of the inner liner 30 after the upper liner ring 31 and the lower liner ring 32 are joined. Specifically, in the embodiments of the present disclosure, the upper liner ring 31 may include a first ring body 313, and the first guide 311 and the second guide 312 both protrude from the lower end face of the first ring body 313 and form the intake notch 301 with the first ring body 313. In the present disclosure, the lower end face of the first ring body 313 is the end face of the first ring body 313 facing toward the lower liner ring 32. After the upper liner ring 31 is installed into the vapor deposition process chamber, the lower end face of the first ring body 313 faces vertically downwards. In this case, the first guide 311 and the second guide 312 not only perform the function of guiding flow but also cooperate with the first ring body 313 to form the intake notch 301, achieving multiple functions with a single component.

In some embodiments, the dimensions of the first guide 311 and the second guide 312 in the direction from the intake side to the exhaust side of the upper liner ring 31 can be 350 mm to 400 mm.

In some embodiments, the dimensions of the first guide 311 and the second guide 312 in the direction protruding from the lower end face of the first ring body 313 can be 24 mm to 30 mm, thereby allowing the process gas to be guided within a sufficiently large flow space.

As described above, an exhaust port 0311 of the inner liner 30 is formed between the second end of the upper liner ring 31 and the second end of the lower liner ring 32, and the exhaust passage 03 includes the exhaust port 0311. As such, in some embodiments, the upper liner ring 31 may further include a baffle 314 located at the exhaust side of the upper liner ring 31. The baffle 314 may protrude from the lower end face of the first ring body 313 and is located at the outer edge of the first ring body 313. The baffle 314 is configured to form a part of the exhaust passage 03 (e.g., the second exhaust section 032 described later) with a part of the outer peripheral wall of the lower liner ring 32, i.e., forming at least a section of space of the exhaust passage 03.

In the present disclosure, an annular groove 302 is formed at the outer peripheral wall of the inner liner 30. The annular groove 302 is located below the transfer port 306 of the inner liner 30. The area of the circular region enclosed by the circular inner wall of the inner liner 30 is a first area, and the cross-sectional area of the annular groove 302 is a second area. The ratio of the first area to the second area is greater than 600. In some embodiments, the inner liner 30 includes an annular liner, and the annular liner is a ring-shaped part of the inner liner 30. The annular liner surrounds the carrier 20. Further, in some embodiments, the outer peripheral wall of the annular liner may have an annular groove 302. The area of the circular region enclosed by the circular inner wall of the annular liner is a first area, and the cross-sectional area of the annular groove 302 is a second area. The ratio of the first area to the second area can be greater than 600.

In some embodiments, when the inner diameter of the inner liner 30 (e.g., the annular liner, the lower liner ring 32) is in the range of 400 mm-600 mm, the ratio of the first area to the second area can be less than 2000, that is, the ratio of the first area to the second area is greater than 600 and less than 2000. In a further technical solution, the ratio of the first area to the second area can be 1050-1350. This solution is more suitable for 12-inch wafer 60.

In some embodiments, when the inner diameter of the inner liner 30 (e.g., the annular liner, the lower liner ring 32) is in the range of 300 mm-500 mm, the ratio of the first area to the second area can be less than 1500, that is, the ratio of the first area to the second area is greater than 600 and less than 1500. In a further technical solution, the ratio of the first area to the second area is 750-900. This solution is more suitable for 8-inch wafer 60.

As described above, the vapor deposition process chamber disclosed in the embodiments of the present disclosure is provided with a process space 01, an intake passage 02, and an exhaust passage 03. The intake passage 02 and the exhaust passage 03 are located at opposite sides of the process space 01 and are respectively connected to the process space 01. The annular liner is arranged around the carrier 20, and the process space can be formed by at least the carrier 20 and the annular liner. The inner liner 30 is disposed within the chamber 10. Both the intake passage 02 and the exhaust passage 03 extend through the chamber 10 and communicate with the process space 01. An annular assembly gap can be formed between the lower liner ring 32 (e.g., annular liner) and the inner wall of the chamber 10. The annular groove 302 communicates with the process space 01, the intake passage 02, and the exhaust passage 03 through the annular assembly gap. The vapor deposition process chamber disclosed in the present disclosure also has a protective gas passage. The protective gas passage is configured to connect to a protective gas source and communicates with the annular groove 302. The protective gas source can provide protective gases, such as argon or hydrogen; the present disclosure does not limit the specific type of protective gas.

The protective gas passage is configured to receive protective gas, allowing the protective gas to enter the annular assembly gap through the annular groove 302 and ultimately forms an annular gas curtain. In this case, the protective gas is ejected from the annular assembly gap, thereby preventing process gases from the intake passage 02, exhaust passage 03, and process space 01 from entering the annular assembly gap and causing undesirable deposition. Clearly, this method avoids undesirable deposition of process gases, thus preventing the need for repeated cleaning of components in the vapor deposition process chamber due to poor deposition. It also reduces the difficulty of cleaning, thereby minimizing cleaning costs and lowering maintenance costs for the vapor deposition process chamber. Furthermore, since some components of the vapor deposition process chamber do not need frequent cleaning, the probability of downtime is reduced, which helps improve the chamber's production capacity.

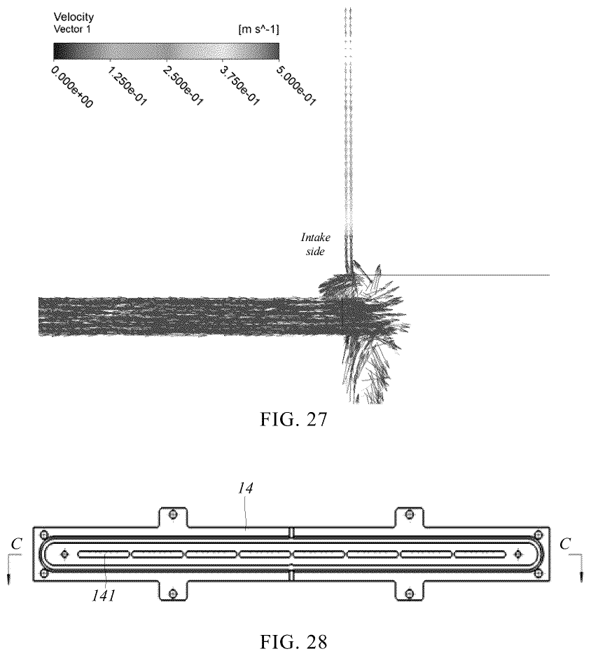

Meanwhile, as shown in FIGS. 26 and 27, further simulation experiments show that when the ratio of the first area to the second area is greater than 600, the protective gas can form an annular gas curtain, effectively preventing process gases from entering the annular assembly gap. When the ratio of the first area to the second area is outside this range, the protective gas struggles to form an annular gas curtain. As shown in FIG. 27, when the ratio of the first area to the second area is less than 600, the protective gas only forms a gas curtain at the intake side, and this curtain is not annular. It should be noted that FIGS. 26 and 27 both illustrate gas flow, with the velocity of the protective gas indicated by the gradient from blue to red.

In the embodiments of the present disclosure, the cross-sectional shape of the annular groove 302 can be rectangular, square, semi-circular, etc., and the embodiments of the present disclosure do not limit the specific shape of the annular groove 302. In the present disclosure, the cross-section of the annular groove 302 refers to the cross-section of the annular groove 302 perpendicular to the extending direction of the annular groove 302. Correspondingly, the cross-sectional area refers to the area of the annular groove 302 in the cross-section perpendicular to the extending direction of the annular groove 302.

As described above, the inner liner 30 includes an upper liner ring 31 and a lower liner ring 32, both annular structures, surrounding the carrier 20. Specifically, the annular liner of the inner liner 30 includes the part of the upper liner ring 31 that surrounds the carrier 20 (i.e., the first ring body 313) and the part of the lower ring 32 that surrounds the carrier 20 (i.e., the second ring body 321). The upper ring 31 is located above the lower ring 32 and is coaxially arranged with the lower ring 32. Specifically, the first ring body 313 is located above the second ring body 321 and is coaxially arranged and connected with the second ring body 321. The annular groove 302 can be provided at the outer peripheral wall of the lower ring 32. Of course, the annular groove 302 can also be provided at the outer peripheral wall of the upper ring 31, or both the outer peripheral walls of the upper ring 31 and the lower ring 32 can be provided with the annular groove 302; the present disclosure does not impose any limitations.

Of course, when the annular groove 302 is provided at the outer peripheral wall of the lower ring 32, the area of the circular region enclosed by the circular inner wall of the lower ring 32 is the first area. When the outer peripheral wall of the upper liner ring 31 has an annular groove 302, the area of the circular region enclosed by the circular inner wall of the upper liner ring 31 is the first area. Furthermore, when both the outer peripheral walls of the upper liner ring 31 and the lower liner ring 32 have annular grooves 302, the areas of the circular regions enclosed by the circular inner walls of the upper liner ring 31 and the lower liner ring 32 are both the first area. That is, the circular region enclosed by the circular inner walls of the upper liner ring 31, the lower liner ring 32, and the inner liner 30 is the same region, and the area of this region is the first area.

As mentioned above, the upper liner ring 31 may include a first ring body 313. Therefore, if the outer peripheral wall of the upper liner ring 31 has an annular groove 302, that means the annular groove 302 is formed at the outer peripheral wall of the first ring body 313. In the present disclosure, the lower liner ring 32 may include a second ring body 321. In this case, if the outer peripheral wall of the lower liner ring 32 has an annular groove 302, that means the annular groove 302 is located at the outer peripheral wall of the second ring body 321. The first ring body 313 is the part of the upper liner ring 31 surrounding the carrier 20, and the second ring body 321 is the part of the lower liner ring 32 surrounding the carrier 20.

In a further technical solution, the lower liner ring 32 may also include an annular flange 322 located at the top of the second ring body 321 and extending inwards towards the second ring body 321. The annular flange 322 supports the preheating ring 70 surrounding the carrier 20. In this case, in addition to protective function and the function of introducing protective gas, the lower liner ring 32 also supports the preheating ring 70, achieving multiple functions with a single component.

To improve the support stability of the carrier 20, an inner edge of the annular flange 322 may have an annular positioning groove 305 for positioning and engaging with the edge of the preheating ring 70. Specifically, the annular positioning groove 305 is shape-fitted to the preheating ring 70, ensuring that the preheating ring 70 will not move within the plane parallel to the carrying surface 21 when placed within the annular positioning groove 305, thereby improving the stability of the support for the preheating ring 70.

In the present disclosure, the outer peripheral wall of the lower liner ring 32 (e.g., the second ring body 321) near the exhaust side may be provided with a recess 303. The recess 303 forms at least a part of the exhaust passage 03 between the recess 303 and the upper liner ring 31. This creates additional space by partially recessing the lower liner ring 32 (e.g., the second ring body 321) to form the recess 303, thereby forming a part of the exhaust passage 03 between the recess 303 and the corresponding position of the upper liner ring 31, further enhancing the utilization of the annular liner and achieving a multi-purpose effect.

In a further technical solution, a gas delivery hole 304 may be provided at one side of the lower liner ring 32 (e.g., the second ring body 321). The gas delivery hole 304 is configured to deliver driving gas. The driving gas may be nitrogen, argon, etc. The embodiments of the present disclosure do not limit the specific type of driving gas. The side of the lower liner ring 32 with the gas delivery hole 304 is the exhaust side of the lower liner ring 32. Specifically, the lower liner ring 32 has a gas delivery hole 304 near the exhaust side. The gas delivery hole 304 extends from the inner peripheral wall (i.e., the circular inner wall of the lower liner ring 32) through the outer peripheral wall of the lower liner ring 32 (e.g., the second ring body 321), and is located above the recess 303, and is configured to communicate with the exhaust passage 03. In a specific process, the waste gas entering the exhaust passage 03 may accumulate. In this case, the driving gas output from the gas delivery hole 304 can enter the exhaust passage 03, thereby promoting the waste gas to be discharged as quickly as possible. In the specific working process, either a high-pressure driving gas or a high-velocity driving gas can be used to drive the exhaust gas; the present disclosure does not impose any limitations. Of course, those skilled in the art should reasonably design the pressure or velocity of the driving gas to ensure that, while fulfilling the function of driving exhaust gas discharge, it does not affect the normal operation of the vapor deposition process or that the impact on the vapor deposition process is within an acceptable range.

The exhaust passage 03 extends to a certain extent in the circumferential direction surrounding the carrier 20; that is, the exhaust passage 03 can be considered an arc-shaped structure. As such, the recess 303 can be an arc-shaped structure extending circumferentially from the lower liner ring 32 (e.g., the second ring body 321). There can be a plurality of gas delivery holes 304 spaced apart along the circumferential direction. Furthermore, the plurality of gas delivery holes 304 can be evenly distributed in the circumferential direction. In this case, the plurality of gas delivery holes 304 simultaneously deliver driving gas to the exhaust passage 03 at different positions, undoubtedly achieving a more balanced and stronger driving effect.

Furthermore, in some embodiments, the flow area of the gas delivery hole 304 decreases towards the recess 303. This increases the pressure and velocity of the driving gas flowing out of the gas delivery hole 304, thereby promoting the rapid discharge of waste gas. In this case, the driving gas is accelerated as flowing through the gas delivery hole 304 due to the decreasing flow area, resulting in a better driving effect. This structure utilizes the Venturi effect; the driving gas is accelerated as flowing through the gas delivery hole 304 with decreasing flow area. The accelerated driving gas can flow out at a higher velocity, thus better driving the process gas to exit.

To enable the wafer 60 to enter and exit the process space 01, the vapor deposition process chamber disclosed in the present disclosure has a transfer port 306 provided in the annular liner. The transfer port 306 can be located at the upper liner ring 31 or the lower liner ring 32; the present disclosure does not impose any limitations. In some embodiments, when the lower liner ring 32 has an annular groove 302 and also a transfer port 306, the annular groove 302 may be located below the transfer port 306. In this case, the protective gas, during the discharge process from the annular assembly gap, passes through the transfer port 306, thereby purging and cleaning the transfer port 306. The transfer port 306 is used for the passage of the wafer 60, allowing the wafer 60 to enter and exit the process space 01.

In some embodiments, the annular groove 302 may be located below the intake passage 02, the exhaust passage 03, and the process space 01.

As described above, the annular groove 302 may be formed at the outer peripheral wall of the annular liner. Of course, the annular groove 302 may also be formed at the inner peripheral wall of the chamber 10. Specifically, the annular groove 302 is provided at the outer peripheral wall of the annular liner and/or the inner peripheral wall of the chamber 10; that is, at least one of the outer peripheral wall of the annular liner or the inner peripheral wall of the chamber 10 has the annular groove 302. In this case, the annular groove 302 can have multiple locations, which undoubtedly improves the flexibility of structural design. Of course, when both the inner peripheral wall of the chamber 10 and the outer peripheral wall of the annular liner have annular grooves 302, it is easier to form a larger structure for the flow of protective gas to meet higher requirements.

Considering that the chamber 10 serves as the main peripheral structure of the entire vapor deposition process chamber and performs multiple functions, in order to reduce the adverse effects of the annular groove 302 on the strength of the chamber 10, in some embodiments, the annular groove 302 is only formed at the outer peripheral wall of the annular liner.

In the embodiments of the present disclosure, the chamber 10 can have various structures and multiple components. In some embodiments, the chamber 10 includes a base ring 13 surrounding the annular liner, an intake passage 02 passing through the annular liner and the base ring 13, and an annular groove 302 is formed at the outer peripheral wall of the annular liner and/or the inner peripheral wall of the base ring 13; that is, at least one of the outer peripheral wall of the annular liner or the inner peripheral wall of the base ring 13 has an annular groove 302. An annular assembly gap can be formed between the annular liner and the base ring 13.

As described above, the inner liner 30 may include an upper liner ring 31 and a lower liner ring 32, with the lower liner ring 32 located below the upper liner ring 31 and coaxially arranged with the upper liner ring 31. In some embodiments, the upper liner ring 31 includes a first ring body 313 surrounding the carrier 20, and the lower liner ring 32 includes a second ring body 321 surrounding the carrier 20. The first ring body 313 and the second ring body 321 located below the first ring body 313 form an annular liner. The first ring body 313 and the second ring body 321 are coaxially arranged and both surround the carrier 20. An intake port 021 is formed between the ends of the upper liner ring 31 and the lower liner ring 32 near the intake side of the inner liner 30. The intake passage 02 includes the intake port 021. An annular groove 302 is formed at the outer peripheral wall of at least one of the first ring body 313 or the second ring body 321. An annular assembly gap is formed between at least one of the first ring body 313 or the second ring body 321 and the chamber 10. In this case, the upper liner ring 31 and lower liner ring 32 each form annular assembly gaps with the chamber 10, making it easier to connect with the annular groove 302 to form more gas curtains, ultimately achieving a better protective effect.

In the present disclosure, the annular assembly gap formed between the inner liner 30 and the chamber 10 is the same as the annular assembly gap formed between the annular liner and the chamber 10. The annular assembly gap can also be considered to be formed between at least one of the upper liner ring 31 or the lower liner ring 32 and the chamber 10.

In a further technical solution, the length of the upper liner ring 31 in the direction perpendicular to the carrying surface 21 of the carrier 20 can be less than the length of the lower liner ring 32 in the direction perpendicular to the carrying surface 21, thereby facilitating the formation of an exhaust structure in the exhaust passage 03 that is lower than the carrying surface 21. Specifically, the length of the first ring body 313 in the direction perpendicular to the carrying surface 21 is less than the length of the second ring body 321 in the direction perpendicular to the carrying surface 21.

Furthermore, the annular groove 302 can be formed at the outer peripheral wall of the lower liner ring 32 and located below the exhaust passage 03, thereby preventing exhaust gas in the exhaust passage 03 from flowing downwards.

As described above, the vapor deposition process chamber disclosed in the present disclosure is provided with an intake passage 02 and an exhaust passage 03, both of the intake passage 02 and the exhaust passage 03 extend through the chamber 10 and the inner liner 30 and communicate with the process space 01. In this case, the annular groove 302 is located below the exhaust passage 03. In some embodiments, the first part of the exhaust passage 03 may include a first exhaust section 031 and a second exhaust section 032. The intake passage 02 has an intake port 021 communicating with the process space 01. The first exhaust section 03 has an exhaust port 0311 communicating with the process space 01. The second exhaust section 032 communicates with the process space 01 through the first exhaust section 031, and the first exhaust section 031 and the second exhaust section 032 intersect. The intake port 021 and the exhaust port 0311 are located at opposite sides of the carrier 20. The axis of the intake port 021 and the axis of the exhaust port 0311 are both parallel to the carrying surface 21 of the carrier 20. The second exhaust section 032 communicates with the second part of the exhaust passage 03, and the second part of the exhaust passage 03 is parallel to the first exhaust section 031. The first exhaust section 031 can be located above the second exhaust section 032, and the annular groove 302 can be located below the junction of the first part and the second part of the exhaust passage 03. Specifically, the annular groove 302 can be located below the junction of the second exhaust section 032 and the second part of the exhaust passage 03. In this structure, the annular groove 302 is located lower than the exhaust passage 03, which can prevent exhaust gas from seeping into deeper parts of the process chamber at the junction of the first part and the second part, achieving a better protective effect.

As described later, the second part can be a third exhaust section 033. In this case, the annular groove 302 can be located below the junction of the second exhaust section 032 and the third exhaust section 033. Further details regarding this structure can be found in the corresponding descriptions below and will not be elaborated upon here.

As described above, the inner liner 30 may include an annular liner, and may also include a first guide 311 and a second guide 312. Specifically, the first guide 311 and the second guide 312 are not the part of the inner liner 30 surrounding the carrier 20, while the annular liner is the part of the inner liner 30 surrounding the carrier 20. In this case, the inner liner 30 includes an annular liner and a first guide 311 and a second guide 312 disposed at the annular liner and protruding axially from the inner liner 30. A first ring body 313 and a second ring body 321 form the annular liner, and the first guide 311 and the second guide 312 may be disposed at the end face of one of the first ring body 313 and the second ring body 321 facing the other. The axial direction of the inner liner 30, the axial direction of the first ring body 313, the axial direction of the second ring body 321, and the axial direction of the annular liner are all consistent, all being the direction of the central axis extending along the through direction of the inner liner 30.

As described above, the first guide 311 and the second guide 312 protrude from the lower end face of the first ring body 313, and conversely, the first guide 311 and the second guide 312 protrude from the upper end face of the second ring body 321.

The upper end face of the second ring body 321 refers to the vertically upward-facing end face of the second ring body 321 when the lower liner ring 32 is installed inside the chamber 10 of the vapor deposition process chamber.

Furthermore, in some embodiments, the first guide 311 and the second guide 312 may be disposed near the top of the inner liner 30, with the annular groove 302 located below the first guide 311 and the second guide 312.

As described above, the vapor deposition process chamber in the present disclosure has an intake passage 02. Since the reactant gas has a high concentration before entering the process space 01, directly disposing the intake passage 02 onto the chamber 10 would have adverse effects on the chamber 10 over time (e.g., severe corrosion, severe erosion, etc.). As such, the present disclosure discloses a gas intake liner 33 for a vapor deposition process chamber. The gas intake liner 33 can be installed in the mounting hole of the chamber 10, and is configured to connect with the intake port 021 of the inner liner 30 described above.

Specifically, the gas intake liner 33 can have multiple gas intake holes 307 arranged in a first direction and isolated from each other. The through directions of the multiple gas intake holes 307 are consistent. In the present disclosure, the first direction is perpendicular to the through directions of the gas intake holes 307.

At least a part of the plurality of gas intake holes 307 is used for introducing process gas. Each of the plurality of gas intake holes 307 corresponds to a specific area within the process space 01. By controlling the gas delivery parameters of the plurality of gas intake holes 307, differentiated control of different regions within the process space 01 can be achieved, thereby realizing zoned control of the process space 01.

Of course, the gas intake liner 33 may also be provided with a single gas intake hole 307. In this case, the process gas can be delivered into the process space 01 through this single gas intake inner liner 307. The present disclosure does not limit the number of gas intake holes 307 provided in the gas intake liner 33.

Adding a gas intake liner 33 minimizes direct contact between the process gas and the chamber 10 during gas introduction, thereby protecting the chamber 10 and preventing excessive corrosion. To facilitate replacement in cases of severe damage to the gas intake liner 33, in some embodiments, the gas intake liner 33 is detachably installed within the chamber 10. Of course, the corrosion resistance of the gas intake liner 33 can be higher than that of the chamber 10. Specifically, the material of the gas intake liner 33 can be quartz. The present disclosure does not limit the material of the gas intake liner 33.

In the present disclosure, the gas intake liner 33 can be an integral structure or a split structure; the present disclosure does not impose any limitations.

In some embodiments, the gas intake liner 33 is an integral structure. It should be noted that an integral structure refers to a structure manufactured using a one-piece molding process. The one-piece molding process can be cutting, casting, injection molding, etc. The gas intake liner is an integral structure, thus forming a single structural component, which undoubtedly reduces the amount of assembly needed when assembling on the chamber 10, and also reduces assembly errors. Specifically, when the gas intake liner 33 is an integral structure, the gas intake liner 33 includes a first assembly 331 and multiple first spacers 332 located within the first assembly 331. That is, the first spacers 332 and the first assembly 331 are integrally formed, and the multiple first spacers 332 divide the space within the first assembly 331 to form multiple gas intake holes 307.

Specifically, the first assembly 331 can be a first flat assembly. The flat structure of the first flat assembly facilitates the formation of flat gas intake holes 307. Of course, the embodiments of the present disclosure do not limit the shape of the first assembly 331 or the shape of the gas intake holes 307, as long as the gas intake liner 33 can mate with the intake port 021.

In some embodiments, the gas intake liner 33 is a split structure. The gas intake liner 33 may include multiple second assemblies 333 arranged sequentially in a first direction, with adjacent second assemblies 333 in contact. In a plurality of second assemblies 333, each of the plurality of second assemblies 333 is configured to form one gas intake hole 307; or, each of the plurality of second assemblies 333 has at least one second spacer 334, so that the second assembly 333 forms at least two gas intake holes 307; or, some second assemblies 333 form one gas intake hole 307, while other second assemblies 333 each have at least one second spacer 334, so that the corresponding second assembly 333 forms at least two gas intake holes 307. This split-type gas intake liner 33 has advantages such as simple structure and flexible design. Furthermore, in the event of partial damage to the gas intake liner 33, only the affected part can be replaced, without replacing the entire gas intake liner 33.

Similarly, the second assembly 333 can be a second flat assembly. The flat structure of the second flat component facilitates the formation of a flat gas intake hole 307. Of course, the embodiments of the present disclosure do not limit the shape of the second assembly 333, nor the shape of the gas intake hole 307, as long as gas intake liner 33 can mate with the intake port 021.

Furthermore, in some embodiments, a second spacer 334 can be provided in each of the two second assemblies 333 located at opposite side edges of the gas intake liner 33, to form two gas intake holes 307 respectively serving as an auxiliary gas intake hole and a process gas intake hole. The process gas intake hole is located at inner side of the auxiliary gas intake hole. The auxiliary gas intake hole introduces auxiliary gas into the process space 01, and the process gas intake hole introduces process gas into the process space 01. The auxiliary gas plays an auxiliary role, and the size of the auxiliary gas intake hole in the first direction can be smaller than the size of the process gas intake hole in the first direction, thereby making the area within the process space 01 corresponding to the auxiliary gas intake hole narrower, while the area within the process space 01 corresponding to the process gas intake hole wider, thus enabling the wider area within the process space 01 to undergo vapor deposition.

In the present disclosure, the dimension of the first spacer 332 or the second spacer 334 in the first direction can be less than 4 mm. This allows for a closer distance between adjacent gas intake holes 307, ensuring that the mixing effect of the process gas after exiting the gas intake holes 307 is not affected, simultaneously preventing a decrease in the concentration of process gas in the area corresponding to the first spacer 332 or the second spacer 334 and the wafer 60, thus avoiding uneven deposition.

In the present disclosure, the gas intake liner 33 can be a flat structure having a top flat wall 308 and a bottom flat wall 309. Both the top flat wall 308 and the bottom flat wall 309 can be parallel to the through directions and the first direction, respectively. The gas intake liner 33 may have two arc-shaped sidewalls 310 respectively forming opposite side edges of the gas intake liner 33. The two arc-shaped sidewalls 310 are arranged opposite each other and protrude in a direction away from each other. Both arc-shaped sidewalls 310 are connected between the top flat wall 308 and the bottom flat wall 309. In this structure, the gas intake liner 33 has a flat structure that can be installed relatively stable through the top flat wall 308 and the bottom flat wall 309. At the same time, the two arc-shaped sidewalls 310 are less prone to stress concentration during or after manufacturing, thus making the structure of the gas intake liner 33 more stable.

In the embodiments of the present disclosure, the gas intake hole 307 can be a circular hole or a flat hole, such as a rectangular hole or an oblong hole. Considering that laminar gas flow makes it easier to achieve a more uniform process effect, in some embodiments, multiple gas intake holes 307 can all be flat holes. The dimension of the gas intake hole 307 in the first direction can be larger than the dimension in the second direction. The second direction is perpendicular to both the through directions and the first direction.

As described above, the plurality of gas intake holes 307 may include auxiliary gas intake holes and process gas intake holes. In some embodiments, among the plurality of gas intake holes 307, two gas intake holes 307 adjacent to two opposite side edges of the gas intake liner 33 are both auxiliary gas intake holes. Other gas intake holes 307 located between two auxiliary gas intake holes are process gas intake holes. In this case, the auxiliary gas intake holes located at the two side edges are responsible for introducing auxiliary gas, thereby achieving the same process objective on both sides of the process space 01.

Since the auxiliary gas input through the auxiliary gas intake holes performs an auxiliary function, the impact on the vapor deposition process is minimized while performing this auxiliary function. For example, the auxiliary gas can be hydrogen or hydrogen chloride gas. The auxiliary gas can improve the concentration of process gas in the gas flow field at the edge of the wafer 60. The auxiliary gas can also be other types of gases that can improve the concentration of process gas in the gas flow field at the edge of the wafer 60; the embodiments of the present disclosure do not limit the specific type of auxiliary gas.

In a further technical solution, the size of the process gas intake hole in the first direction can be larger than the size of the auxiliary gas intake hole in the first direction. In some embodiments, the intake width formed by the plurality of gas intake holes 307 in the first direction is a first intake width, and the intake width formed by the two auxiliary gas intake holes in the first direction is a second intake width. The ratio of the second intake width to the first intake width can be 1:25 to 1:10. Within this ratio range, the width of the auxiliary gas flow formed after the auxiliary gas is output will not occupy a large width, thus improving the concentration of process gas in the gas flow field at the edge of the wafer 60 without affecting the concentration of process gas in the gas flow field of other regions of the wafer 60.

The gas intake liner 33 disclosed in the present disclosure is applied in a vapor deposition process chamber. The auxiliary gas intake holes can be facing towards the inner side of the edge of the carrier 20, thereby indirectly facing towards the inner side of the edge of the wafer 60 placed on the carrier 20. In this case, the auxiliary gas can be a gas that can participate in a certain reaction while also being able to suppress vapor deposition to a limited extent, such as hydrogen chloride. The auxiliary gas can suppress the chemical reaction at the edge of the wafer 60, thereby making the thickness of the deposited material at the edge of the wafer 60 smaller and meeting some preset requirements.

In some embodiments, the auxiliary gas intake hole can be facing towards the outer side of the edge of the carrier 20, thereby indirectly facing towards the outer side of the edge of the wafer 60 placed on the carrier 20. In this case, the area corresponding to the auxiliary gas is offset from the wafer 60 and the auxiliary gas does not participate in the vapor deposition reaction, while also providing a certain degree of isolation, thereby preventing undesirable deposition of process gases on the outer side of the edge of the wafer 60 and helping to reduce deposition by-products at the edge of the wafer 60.

As described above, the inner liner 30 may include an annular liner having an intake port 021 facing the gas intake liner 33 and an exhaust port 0311 facing away from the gas intake liner 33. The gas intake hole 307 of the gas intake liner 33 communicates with the process space 01 through the intake port 021, and the exhaust port 0311 communicates with the process space 01, that is, the exhaust port 0311 of the exhaust passage 03 communicates with the process space 01.

In the case where the annular liner has a split structure, the annular liner includes an upper liner ring 31 and a lower liner ring 32 located below the upper liner ring 31, both are annular structures. The upper liner ring 31 and the lower liner ring 32 are coaxially arranged and both surround the carrier 20. An intake port 021 is formed between the ends of the upper liner ring 31 and the lower liner ring 32 near the gas intake liner 33. That is, an intake port 021 is formed between the ends of the upper liner ring 31 and the lower liner ring 32 near the gas intake side of the inner liner 30. An exhaust port 0311 is formed between the ends of the upper liner ring 31 and the lower liner ring 32 near the exhaust side of the inner liner 30.

The vapor deposition process chamber disclosed in the present disclosure is equipment for performing vapor deposition processes and determines the quality of the vapor deposition process. Ensuring the uniformity of the process gas in the vapor deposition process chamber is a crucial factor in determining the quality of the vapor deposition process. During the vapor deposition process, process gases tend to converge towards the exhaust passage 03 when flowing towards the area near the exhaust passage 03, and then exit too quickly through the exhaust passage 03. This convergence of process gases within the process space 01 and the rapid exit of the process gas from the vapor deposition process chamber easily leads to uneven distribution of process gases in the area near the exhaust passage 03 within the vapor deposition process chamber.

To improve the uniformity of process gases in the area near the exhaust passage 03 within the process space 01, a flow equalizer is installed at the exhaust passage 03. The flow equalizer has multiple flow equalization holes arranged in an array. The flow equalizer allows process gases from multiple locations to flow into the corresponding flow equalization holes and then into the exhaust passage 03. This can alleviate the convergence of process gases to some extent. At the same time, the flow equalizer also acts as a barrier, thus preventing the process gases from exiting too quickly.

However, this structure still has drawbacks. The flow equalizer significantly obstructs the process gas, resulting in a slow exhaust velocity. This makes it easier for a large amount of process gas to deposit on the inner wall or components near the exhaust passage 03 within the vapor deposition chamber, an undesirable outcome for process engineers. Simultaneously, the small aperture of the flow equalization hole of the flow equalizer abruptly reduces the flow area of the process gas as the process gas passes through the flow equalization hole, making the process gas more prone to turbulent gas flow in the region near the exhaust passage 03 within the vapor deposition chamber. Ultimately, this results in poor uniformity of the process gas in this region (i.e., the area near the exhaust passage 03 within the vapor deposition chamber). In other words, poor uniformity of the process gas in this region may still affect the thickness uniformity of the vapor-deposited film, ultimately leading to poor process quality.

As such, the vapor deposition chamber disclosed in the present disclosure also works on the exhaust passage 03, and the exhaust passage 03 includes a first exhaust section 031 and a second exhaust section 032 that are interconnected.

The intake passage 02 has an intake port 021 communicating with the process space 01. The intake passage 02 is configured to supply the process gas needed for the vapor deposition process into the process space 01 through the intake port 021. The first exhaust section 031 has an exhaust port 0311 communicating with the process space 01. During the vapor deposition process, the process gas (i.e., waste gas) that has completed the vapor deposition process first enters the first exhaust section 031 from the process space 01 through the exhaust port 0311, then flows from the first exhaust section 031 into the second exhaust section 032, and finally is discharged through the exhaust passage 03.

In the present disclosure, the intake port 021 and the exhaust port 0311 are located at opposite sides of the carrier 20, and the axes of both the intake port 021 and the exhaust port 0311 can be parallel to the carrying surface 21 of the carrier 20. This allows the process gas entering the process space 01 through the intake port 021 to flow over the carrier 20 in a direction parallel to the carrying surface 21, and then enter the exhaust port 0311 in the same direction. In other words, the process gas flows through the carrying surface 21 in a laminar flow manner in a direction parallel to the carrying surface 21 as the process gas flows out of the intake port 021 and into the exhaust port 0311.

To achieve flow in a direction parallel to the carrying surface 21, in some embodiments, the intake port 021, the exhaust port 0311, and the carrying surface 21 can be located at the same height within the process space 01; that is, the lower edge of the intake port 021, the lower edge of the exhaust port 0311, and the carrying surface 21 are all located at the same height within the process space 01; or, the axis of the intake port 021, the axis of the exhaust port 0311, and the carrying surface 21 are all located at the same height within the process space 01. In some embodiments, the height of the carrying surface 21 can be slightly smaller than the height of the intake port 021 and the exhaust port 0311, so that after the wafer 60 is placed on the carrying surface 21, the surface of the wafer 60 facing away from the carrying surface 21 (i.e., the base surface for depositing the thin film) is exactly at the same height within the process space 01 as the intake port 021 and the exhaust port 0311. In this case, the difference between the height of the carrying surface 21 and the height of the intake port 021 is within a preset difference value, or the difference between the height of the carrying surface 21 and the height of the exhaust port 0311 is within a preset difference value. The present disclosure does not limit the preset difference value; those skilled in the art can reasonably determine the preset difference value based on the thickness of wafer 60 of different types and models.

Of course, regardless of the structure, during the vapor deposition process, the process gas must be able to glide across the base surface of the wafer 60 in a direction parallel to the carrying surface 21 to achieve laminar flow of the process gas as much as possible, thereby minimizing gas flow turbulence. In the present disclosure, the process gas flows through the carrying surface 21 in a laminar flow manner can be considered as the flow direction of the process gas being parallel to the carrying surface 21, and the process gas will not be disturbed in directions non-parallel to the carrying surface 21 (i.e., the turbulence described above).

As mentioned above, the exhaust passage 03 includes a first exhaust section 031 and a second exhaust section 032 that are interconnected. Specifically, the second exhaust section 032 is connected to the process space 01 through the first exhaust section 031, and the first exhaust section 031 and the second exhaust section 032 intersect. In other words, the extending direction of the first exhaust section 031 is not the same as the extending direction of the second exhaust section 032. The intersecting first exhaust section 031 and second exhaust section 032 allow the process gas, after entering the first exhaust section 031 through the exhaust port 0311, to then change direction and enter the second exhaust section 032, ultimately achieving discharge. During this process, the process gas needs to change direction as the process gas flows towards the second exhaust section 032, thus being blocked to a certain extent and slowed down. In some embodiments, the first exhaust section 031 and the second exhaust section 032 can be perpendicular, that is, the angle between the extending directions of the first exhaust section 031 and the second exhaust section 032 is 90°. Of course, the angle between the extending directions of the first exhaust section 031 and the second exhaust section 032 can also be other angles, such as 30°, 45°, 60°, 80°, etc. The present ;disclosure does not limit the angle between the extending directions of the first exhaust section 031 and the second exhaust section 032.

During the vapor deposition process, the process gas enters the process space 01 through the intake port 021 and passes through the wafer 60 supported by the carrier 20 to achieve deposition on the wafer 60. After passing through the wafer 60, the process gas finally enters the first exhaust section 031 through the exhaust port 0311. Since the first exhaust section 031 and the second exhaust section 032 intersect, the process gas will change direction and enter the second exhaust section 032, ultimately achieving discharge.

The vapor deposition process chamber disclosed in the present disclosure, by designing the exhaust passage 03 to include a first exhaust section 031 and a second exhaust section 032, and ensuring that the first exhaust section 031 and the second exhaust section 032 intersect, allows the process gas to be decelerated during discharge after participating in the vapor deposition process due to direction change. This reduces the flow velocity of the process gas in the area near the exhaust passage 03 within the process space 01, thus avoiding gas flow turbulence caused by excessively rapid process gas discharge. This improves the uniformity of the process gas and ultimately enhances the thickness uniformity of the film formed by the vapor deposition process.

Simultaneously, this structure avoids the need for flow equalizer near the exhaust passage 03 within the process space 01, thus preventing excessive obstruction of the process gas. Furthermore, during the exhaust process, the process gas can directly enter the exhaust passage 03 from the process space 01 through the exhaust port 0311, thereby mitigating the gas flow turbulence caused by the sudden reduction in flow area. This further improves the uniformity of the process gas in the area near the exhaust passage 03 within the process space 01.

In addition, the vapor deposition process chamber disclosed in the present disclosure does not need additional flow equalizer on the exhaust path, thus saving the additional manufacturing costs incurred due to the addition of flow equalizer.

In the process chamber disclosed in the present disclosure, the structure of the chamber 10 can be varied, and correspondingly, the structures forming the first exhaust section 031 and the second exhaust section 032 can also be varied. The present disclosure does not limit the specific structure of the chamber 10, and correspondingly, the present disclosure does not limit the structures forming the first exhaust section 031 and the second exhaust section 032.

As described above, the vapor deposition process chamber disclosed in the present disclosure includes a chamber 10, a carrier 20, and an inner liner 30 disposed within the chamber 10. The inner liner 30 can be the inner liner described in the above embodiments, and the inner liner 30 can be a split structure. At least the annular liner and the carrier 20 enclose a process space 01. The inner liner 30 has an intake port 021 facing the gas intake liner 33 and an exhaust port 0311 facing away from the gas intake liner 33.

The inner liner 30 may include an upper liner ring 31 and a lower liner ring 32 located below the upper liner ring 31, both of the upper liner ring 31 and the lower liner ring 32 are annular structures. The upper liner ring 31 and the lower liner ring 32 are coaxially arranged and both surround the carrier 20. The intake port 021 is formed between the ends of the upper liner ring 31 and the lower liner ring 32 near the intake side of the inner liner 30. Specifically, a first exhaust section 031 and a second exhaust section 032 are formed between the upper liner ring 31 and the lower liner ring 32. In the present disclosure, the first exhaust section 031 and the second exhaust section 032 can form the entire exhaust passage 03, or only form a part of the exhaust passage 03. For example, the exhaust passage 03 may include a first part including the first exhaust section 031 and the second exhaust section 032.

In this case, the upper liner ring 31 and the lower liner ring 32 can also form the first exhaust section 031 and the second exhaust section 032, thereby enabling the upper liner ring 31 and the lower liner ring 32 to have other functions in addition to protective function, achieving a dual-purpose effect.

When the inner liner 30 includes the upper liner ring 31 and the lower liner ring 32, the upper liner ring 31 is located above the lower liner ring 32. In a further technical solution, a protrusion 315 can be provided in the first exhaust section 031 near the exhaust port 0311. The upper liner ring 31 forms the top wall of the first exhaust section 031, and the lower liner ring 32 forms the bottom wall of the first exhaust section 031. The protrusion 315 is provided at the part of the upper liner ring 31 that forms the top wall of the first exhaust section 031. The protrusion 315 is provided at the top wall of the first exhaust section 031. This structural design allows the flow area of the exhaust port 0311 to be smaller, making it easier for the flow area of the exhaust port 0311 to be smaller than the flow area of other parts of the exhaust passage 03. This makes it easier for the exhaust passage 03 to form an exhaust structure with a small inlet and a large outlet. The smaller inlet of the exhaust passage 03 can also alleviate the phenomenon of excessively rapid discharge of process gas to a certain extent. The larger outlet of the exhaust passage 03 can prevent the process gas from being discharged too slowly once the process gas enters the exhaust passage 03, thus preventing gas accumulation. Since the front of the exhaust passage 03 is a small inlet and close to the process space 01, in a high-temperature environment, byproducts (coating) generated during the process adhere to the front side. Subsequent introduction of etching gas into the process space 01 can etch away the coating, and the accelerated exhaust from the rear side significantly reduces coating, avoiding the problem of coating formation on the rear side that is difficult to etch away.

Furthermore, the protrusion 315 adds an extra area at the exhaust port 0311, and since the exhaust port 0311 is closer to the high-temperature process space 01, the process gas can be deposited as much as possible on the surface of the protrusion 315 facing the process space 01 during the exhaust process. The surface of the protrusion 315 facing the process space 01 is part of the inner wall of the vapor deposition process chamber, making it easier to remove the byproducts deposited on the protrusion 315 during subsequent cleaning and etching processes. This prevents excessive deposition of process gas in deeper parts of the exhaust passage, which would be difficult to clean and etch away.

Consistent with the present disclosure, the upper liner ring 31 is located above the lower liner ring means that, in the vertical direction, the part of the upper liner ring 31 corresponding to the part of the lower liner ring 32 is higher than the corresponding part of the lower liner ring 32. In some embodiments, all parts of the upper liner ring 31 can be higher than the entire lower liner ring 32.

As mentioned above, the upper liner ring 31 and the lower liner ring 32 can form a first exhaust section 031 and a second exhaust section 032. Specifically, different parts of the upper liner ring 31 and the lower liner ring 32 can be spaced apart to form the first exhaust section 031 and the second exhaust section 032, respectively. As such, in some embodiments, a baffle 314 may be provided at the outer edge of the upper liner ring 31 facing away from the carrier 20. The baffle 314 is located at the outer side of the lower liner ring 32 facing away from the carrier 20 (i.e., the outer peripheral wall of the lower liner ring 32), and a second exhaust section 032 is formed between the baffle 314 and the outer peripheral wall of the lower liner ring 32 facing away from the carrier 20 (a part of the outer peripheral wall of the lower liner ring 32). An exhaust port 0311 is formed between the inner edge of the upper liner ring 31 facing towards the carrier 20 and the inner edge of the lower liner ring 32 facing towards the carrier 20.

The upper liner ring 31 may have a lower end face (i.e., the lower end face of the first ring body 313) located between the exhaust port 0311 and the second exhaust section 032 and facing downwards. The lower liner ring 32 may have an upper end face (i.e., the upper end face of the second ring body 321) located between the exhaust port 0311 and the second exhaust section 032 and facing upwards. The first exhaust section 031 can be formed between the lower end face and upper end face.

This method of forming the first exhaust section 031 and the second exhaust section 032 by spaced-apart arrangement of different parts of the upper liner ring 31 and lower liner ring 32 has the advantage of structural simplicity.

Specifically, the upper liner ring 31 may include the first ring body 313 and a baffle 314 located at the exhaust side of the inner liner 30 and protruding from the lower end face of the first ring body 313. The baffle 314 is located at the outer edge of the first ring body 313.

To facilitate the formation of the second exhaust section 032 or the formation of a second exhaust section 032 with a larger flow area, in some embodiments, a recess 303 may be provided at the outer peripheral wall of the lower liner ring 32 near the exhaust side. The recess 303 corresponds to and is spaced apart from the baffle 314 to form the second exhaust section 032. Specifically, the lower liner ring 32 includes a second ring body 321, and the recess 303 is provided at the outer peripheral wall of the second ring body 321 near the exhaust side.

As mentioned above, the first exhaust section 031 and the second exhaust section 032 intersect, that needs a direction change of the process gas as the process gas enters the second exhaust section 032 from the first exhaust section 031. During this direction change, the process gas is prone to turbulence, especially at the junction of the first exhaust section 031 and the second exhaust section 032, where blockage is more likely to occur. In this case, the process gas is more likely to deposit inside the first exhaust section 031 and the second exhaust section 032. Therefore, in a further technical solution, the inner liner 30 may be provided with a gas delivery hole 304. The gas delivery hole 304 extends from the circular inner wall of the inner liner 30 to the outer peripheral wall of the inner liner 30 and communicates with the exhaust passage 03. Specifically, the driving gas delivery hole 304 is located in the lower liner ring 32 and extends from the circular inner wall of the lower liner ring 32 to the outer peripheral wall of the lower liner ring 32. The gas delivery hole 304 communicates with the second exhaust section 032 and delivers driving gas to the end of the second exhaust section 032 furthest from the first exhaust section 031, thereby accelerating the discharge of the process gas in the second exhaust section 032. This structure prevents the process gas already in the exhaust passage from becoming clogged, allowing for smoother discharge.

In some embodiments, the gas delivery hole 304 can be perpendicular to the second exhaust section 032. Of course, the present disclosure does not limit the angle between the flow direction of the driving gas and the flow direction of the process gas delivered in the second exhaust section 032, as long as the driving gas delivered by the gas delivery hole 304 can be delivered to the end of the second exhaust section 032 away from the first exhaust section 031, thereby facilitating faster discharge of the process gas from the second exhaust section 032.

In the present disclosure, the structure of the gas delivery hole 304 can be varied. For example, the gas delivery hole 304 can be a constant diameter hole or a non-constant diameter hole. The present disclosure does not limit the specific shape of the gas delivery hole 304, as long as the gas delivery hole 304 can deliver the driving gas to the second exhaust section 032 and accelerate the flow of the process gas in the second exhaust section 032. In a further technical solution, the flow area of the gas delivery hole 304 can decrease in the direction near the second exhaust section 032 (i.e., the direction near the exhaust side). In other words, the flow area of the gas delivery hole 304 decreases in the direction of driving gas delivery. In this configuration, the driving gas is accelerated as flowing through the gas delivery hole 304 due to the decreasing flow area, resulting in a better driving effect. This structure utilizes the Venturi effect; the driving gas is accelerated as flowing through the gas delivery hole 304 with decreasing flow area. The accelerated driving gas can then flow out at a higher velocity, thus better driving the process gas in the second exhaust section 032 to exit.

The gas delivery hole 304 can be one or more. In the present disclosure, both the first exhaust section 031 and the second exhaust section 032 are arc-shaped structures extending along the circumferential direction of the inner liner 30. In some embodiments, there are a plurality of gas delivery holes 304, spaced apart along the extending direction of the arc-shaped structure within the corresponding region. In this case, the plurality of gas delivery holes 304 can deliver gas to the end of the second exhaust section 032 away from the first exhaust section 031 from a wider dimension, thereby achieving a better driving effect.

In the present disclosure, the process gas can be directly discharged from the second exhaust section 032 to the outside of the process chamber, or indirectly discharged to the outside of the process chamber through additional structures. In a specific embodiment, the vapor deposition process chamber may be provided with a third exhaust section 033. The first exhaust section 031 and the third exhaust section 033 may be connected to two ends of the second exhaust section 032, respectively, and extend in opposite directions. The first exhaust section 031 extends towards the process space 01 relative to the second exhaust section 032, while the third exhaust section 033 extends in the opposite direction, thereby facilitating the extraction and discharge of the process gas away from the process space 01. In some embodiments, the third exhaust section 033 may be perpendicular to the second exhaust section 032. Of course, the present disclosure does not limit the specific angle between the third exhaust section 033 and the second exhaust section 032. The third exhaust section 033 is also part of the exhaust passage 03 herein; specifically, the third exhaust section 033 can be considered as the second part of the exhaust passage 03.

The present disclosure does not limit the specific component on which the third exhaust section 033 is located within the vapor deposition process chamber. In some embodiments, the chamber 10 may include a base ring 13 surrounding the carrier 20. The third exhaust section 033 may be formed at the base ring 13 and extend radially along the base ring 13.

More specifically, the carrying surface 21 may be parallel to the horizontal plane. The first exhaust section 031 may be a horizontal exhaust section parallel to the carrying surface 21. The second exhaust section 032 may be perpendicular to the first exhaust section 031, i.e., the second exhaust section 032 may be a vertical exhaust section perpendicular to the carrying surface 21. The third exhaust section 033 may be parallel to the first exhaust section 031. When the first exhaust section 031 is parallel to the horizontal plane, the third exhaust section 033 may extend horizontally to the outer wall of the chamber 10 in a direction away from the process space 01. The outer wall of the chamber 10 can be a sidewall of the chamber 10 extending vertically, facilitating connection to subsequent exhaust pipes.

To further facilitate the discharge of process gas, the gas delivery hole 304 can be located at the junction of the third exhaust section 033 and the second exhaust section 032. This arrangement is more conducive to the driving gas output from the gas delivery hole 304 driving the process gas from the second exhaust section 032 to the third exhaust section 033, thus better preventing the process gas from stagnating in the second exhaust section 032.

In a further technical solution, the third exhaust section 033 can be parallel to the first exhaust section 031. The third exhaust section 033 has a first hole wall away from the first exhaust section 031 and a second hole wall close to the first exhaust section 031. The distance between the gas delivery hole 304 and the first hole wall can be a third distance, and the distance between the gas delivery hole 304 and the second hole wall can be a fourth distance. The third distance can be greater than the fourth distance. In this configuration, the gas delivery hole 304 is located relatively far from the outlet of the second exhaust section 032, facilitating the accelerated discharge of the process gas within the second exhaust section 032.

As mentioned above, the gas delivery hole 304 is configured to deliver the driving gas. Specifically, the gas delivery hole 304 can be directly connected to the driving gas source. In some embodiments, the gas delivery hole 304 can be indirectly connected to the driving gas source. As such, in some embodiments, the chamber 10 can be provided with a driving gas chamber 04, and the gas delivery hole 304 can connect the driving gas chamber 04 to the second exhaust section 032, with the driving gas chamber 04 also connected to the driving gas source. In this configuration, the gas delivery hole 304 can be configured with a smaller aperture, while the driving gas chamber 04 can be configured with a larger volume. When the driving gas enters the gas delivery hole 304 from the driving gas chamber 04, the driving gas is moving from a larger volume space to a smaller volume space. During this process, the driving gas is accelerated due to the reduced flow area. With the flow area of the gas delivery hole 304 gradually decreasing in the direction near the second exhaust section 032, the driving gas entering the gas delivery hole 304 can be further accelerated, ultimately allowing the driving gas to flow out at a higher velocity, thus achieving a better driving effect on the process gas.

As mentioned above, the structure of the chamber 10 can vary. In some embodiments, the chamber 10 may include a gas intake seat 14 and a base ring 13, with the base ring 13 surrounding the carrier 20 and the inner liner 30. The gas intake seat 14 has multiple gas input passages 141 spaced apart, and the width of the gas input passages 141 increases in the gas intake direction.

The width of the gas input passages 141 is perpendicular to the gas intake direction and parallel to the carrying surface 21 of the carrier 20. This structure allows the cross-sectional area of the gas input passages 141 to decrease in the gas intake direction. The cross-section of the gas input passage 141 is the cross-section of the gas input passage 141 perpendicular to the gas intake direction (the through direction of the gas intake hole 307). The cross-sectional area of the gas input passage 141 increases in the gas intake direction, enabling the gas input passage 141 to form a funnel-like structure. This structure allows for a smaller distance between the outlet ports of two adjacent gas input passages 141, thereby enabling the process gases output through multiple gas input passages 141 to mix in advance, thus extending the pre-mixing time and making it easier to achieve more uniform mixing in the subsequent process space 01. This undoubtedly benefits the improvement of vapor deposition quality. It should also be noted that when the vapor deposition process chamber includes the gas input passage 141, the intake passage 02 may include the gas input passage 141, the gas intake hole 307, and the intake port 021.

In a more specific structure, the chamber 10 may also include a top cover 11 and a bottom cover 12. The top cover 11 and bottom cover 12 are respectively connected to the two ports of the base ring 13, thus forming most of the peripheral structure of the chamber 10 together with the base ring 13. The top cover 11, bottom cover 12, and base ring 13 enclose the chamber space 05 of the chamber 10. The process space 01 is at least a part of the chamber space 05, and the chamber space 05 may also include the driving gas chamber 04 described above. The carrier 20 is disposed within the chamber space 05. The upper liner ring 31 is detachably disposed at the inner wall of the top cover 11 and part of the inner wall of the base ring 13. The upper liner ring 31 is configured to protect the top cover 11 and the base ring 13. The lower liner ring 32 is detachably disposed at part of the inner wall of the base ring 13, and the process space 01 is formed by at least the upper liner ring 31, the lower liner ring 32, and the carrier 20. The lower liner ring 32 is configured to cooperate with other components to form the process space 01 and also to protect the base ring 13.

The upper liner ring 31 and lower liner ring 32 not only form the first exhaust section 031 and second exhaust section 032, but also serve to receive the thin films generated by process gas deposition during the vapor deposition process, preventing these process gases from depositing directly on the top cover 11, bottom cover 12, and base ring 13. When cleaning is needed, operators only need to remove the upper liner ring 31 and lower liner ring 32 for cleaning, eliminating the need to clean the bulky top cover 11, bottom cover 12, and base ring 13. Furthermore, the upper liner ring 31 and lower liner ring 32 also protect the top cover 11, bottom cover 12, and base ring 13.

Of course, when the chamber 10 includes the top cover 11, bottom cover 12, and base ring 13, and the chamber 10 is provided with a driving gas chamber 04, the bottom cover 12, the carrier 20, and the lower liner ring 32 can form the driving gas chamber 04. The driving gas chamber 04 can be located below the carrier 20.

In some embodiments, the top cover 11 may at least form the chamber top wall 111 of the chamber 10, located above the inner liner 30. The chamber top wall 111 is situated above the carrier 20 and protrudes towards the carrier 20. This design allows the chamber top wall 111 to protrude towards the carrier 20 as the process gas is consumed and concentration of the process gas decreases, thereby reducing the distance between the chamber top wall 111 and the carrier 20, and consequently reducing the size of the space occupied by the process gas. Ultimately, this helps to increase the concentration of the process gas as the process gas flows towards the exhaust side. Specifically, the chamber top wall 111 may be a spherical top wall protruding towards the carrier 20.

In a further technical solution, the vapor deposition process chamber disclosed in the present disclosure may further include multiple gas intake pipes 15 connected to a gas intake seat 14 and respectively connected to a corresponding gas input passage 141. Each of the multiple gas intake pipes 15 may be equipped with a flow control valve controlling the gas intake volume of the corresponding gas intake pipe 15. This allows the multiple gas input passages 141 connected to the multiple gas intake pipes 15 to cooperate with each other, ensuring that the gas flow entering the process space 01 is as uniform as possible through the coordination of gas intake volumes. Simultaneously, the flow control valve facilitates flow control.

In some embodiments, the third exhaust section 033 mentioned above may be located at the base ring 13. In a further technical solution, the vapor deposition process chamber disclosed in the present disclosure may further include a gas exhaust seat 16 located at the outer wall of the base ring 13 and connected to the third exhaust section 033.

In the vapor deposition process, the temperature within the process space 01 needs to meet preset requirements. Therefore, the vapor deposition process chamber disclosed in the present disclosure may further include an upper heating module 40 disposed at chamber 10 and located above the carrier 20. The upper heating module 40 is configured to heat the carrier 20 from above, thereby achieving heating of the wafer 60 supported on the carrier 20 during the vapor deposition process.

In the present disclosure, the structure and type of the upper heating module 40 can be varied, and the present disclosure does not limit the specific structure and type of the upper heating module 40. For example, the upper heating module 40 may include multiple light-emitting heating members arranged in a circle above the carrier 20, emitting light from above the carrier 20 towards the wafer 60 on the carrier 20 to achieve heating. Of course, this distribution method can only result in a higher temperature in a certain ring region on the wafer 60 of the carrier 20, while the temperature in other regions may be lower. Overall, this structure of the upper heating module 40 will still lead to uneven temperature within the process space 01.

Therefore, in some embodiments, the present disclosure discloses a more specific upper heating module 40 including a plurality of first outer heating lamps 41, a plurality of first inner heating lamps 42, a first reflector 43, and a second reflector 44. The carrier 20 includes a central region and an annular region surrounding the central region. The plurality of first outer heating lamps 41 and the plurality of first inner heating lamps 42 are distributed along the circumference of the annular region, and the plurality of first outer heating lamps 41 are located outside the plurality of first inner heating lamps 42. The first reflector 43 is configured to reflect the light projected by the plurality of first outer heating lamps 41 to the annular region, and the second reflector 44 is configured to reflect the light projected by the plurality of first inner heating lamps 42 to the central region. This solution enables the upper heating module 40 to perform zoned heating of the carrier 20, thus effectively regulating the temperature of different regions of the carrier 20.

Simultaneously, during the heating process, multiple first outer heating lamps 41 and multiple first inner heating lamps 42 can be controlled individually, achieving more flexible temperature control and improving the uniformity of the temperature field within the process space 01.

Since both the multiple first outer heating lamps 41 and the multiple first inner heating lamps 42 can all project onto the top of the carrier 20, considering that the annular region is close to the edge of the carrier 20 while the central region is located at the center of the carrier 20, heat is more likely to accumulate in the central region, causing the temperature of the central region to be higher than that of the annular region. Therefore, in a further technical solution, the height of the multiple first outer heating lamps 41 is less than the height of the multiple first inner heating lamps 42; in other words, the distance between the multiple first outer heating lamps 41 and the carrier 20 is less than the distance between the multiple first inner heating lamps 42 and the carrier 20. In this case, the multiple first inner heating lamps 42, due to large distance, will not deliver much heat to the central region, thus making it easier to achieve temperature uniformity between the central region and the outer annular region.

Similarly, to better ensure the process temperature, the process chamber disclosed in the present disclosure may also include a lower heating module 50. The lower heating module 50 is disposed at the chamber 10 and located below the carrier 20. The lower heating module 50 is configured to heat the carrier 20 from below.

In the present disclosure, the structure and type of the lower heating module 50 can be varied, and the present disclosure does not limit the specific structure and type of the lower heating module 50. For example, the lower heating module 50 may also include multiple light-emitting heating members arranged in a circle and distributed below the carrier 20, emitting light from below the carrier 20 to achieve heating. Of course, this distribution method can only result in a higher temperature in a certain ring region on the wafer 60 of the carrier 20, while the temperature in other regions may be lower, leading to uneven temperature within the process space 01.

Similarly, the present disclosure discloses a specific structure for a lower heating module 50. The disclosed lower heating module 50 may include multiple second outer heating lamps 51, multiple second inner heating lamps 52, a third reflector 53, and a fourth reflector 54. Likewise, when the carrier 20 includes a central region and an annular region surrounding the central region, the multiple second outer heating lamps 51 and the multiple second inner heating lamps 52 are distributed along the circumference of the annular region, and the multiple second outer heating lamps 51 are located outside the multiple second inner heating lamps 52. The third reflector 53 is configured to reflect the light projected by the multiple second outer heating lamps 51 to the annular region, and the fourth reflector 54 is configured to reflect the light projected by the multiple second inner heating lamps 52 to the central region. This solution enables the lower heating module 50 to perform zoned heating of the carrier 20, thereby better balancing the temperature regulation of different regions of the carrier 20.

Meanwhile, during the heating process, the multiple second outer heating lamps 51 and the multiple second inner heating lamps 52 can be controlled individually, allowing for more flexible temperature control and improving the uniformity of the temperature field within the process space 01.

Similarly, since both the second outer heating lamps and second inner heating lamps 51 and 52 can project heat onto the carrier 20, and considering that the annular region is closer to the edge of the carrier 20 while the central region is located at the center, heat is more likely to accumulate in the central region, causing the temperature of the central region to be higher than the annular region. Therefore, in a further technical solution, the height of the second inner heating lamps 52 is greater than the height of the second outer heating lamps 51. In other words, the distance between the second inner heating lamps 52 and the carrier 20 is greater than the distance between the second outer heating lamps 51 and the carrier 20. In this case, due to the greater distance, the second inner heating lamps 52 will not deliver much heat to the central region, thus ensuring that the temperature of the central region is consistent with that of the outer annular region.

To further optimize the regulation effect, in a further technical solution, the reflection angle of at least one of the first reflector 43, the second reflector 44, the third reflector 53, or the fourth reflector 54 is adjustable. Specifically, at least one of the first reflector 43, the second reflector 44, the third reflector 53, or the fourth reflector 54 can be individually configured with a driving mechanism. The driving mechanism drives the first reflector 43, the second reflector 44, the third reflector 53, and the fourth reflector 54 to rotate, thereby adjusting the tilt angle of the reflecting surface, thus achieving the purpose of adjustable reflection angle. Various types of driving mechanisms can be used, such as linkage driving mechanisms and motor driving mechanisms. The present disclosure does not limit the specific type of driving mechanism.

Based on the vapor deposition process chamber disclosed in the present disclosure, the present disclosure discloses the semiconductor process equipment. The disclosed semiconductor process equipment includes a transfer chamber and the vapor deposition process chamber described in the above embodiment. The transfer chamber cooperates with the vapor deposition process chamber to realize the entry and exit of the wafer 60 into the vapor deposition process chamber.

The semiconductor process equipment disclosed in the present disclosure can be epitaxial growth equipment, or other equipment used for depositing thin films on wafers using vapor deposition processes. The present disclosure does not limit the specific type of semiconductor process equipment.

The foregoing embodiments of the present application mainly describe differences among the respective embodiments; the different technical features of the embodiments may be combined to form more specific embodiments as long as no conflict exists, and details are not repeated herein for brevity.

The embodiments of the present disclosure have been described above with reference to the accompanying drawings. The present disclosure is not limited to the specific embodiments described above. The specific embodiments described above are merely illustrative and not restrictive. Those skilled in the art, under the guidance of the present disclosure, can make many modifications without departing from the spirit and scope of the claims, all of which fall within the scope of the present disclosure.

What is claimed is:

1. A gas intake liner for a vapor deposition process chamber, configured to connect with an intake port of an inner liner of the vapor deposition process chamber, the gas intake liner having a plurality of gas intake holes arranged in a first direction and isolated from each other, the plurality of gas intake holes having a same through direction, and the first direction being perpendicular to the through direction of the plurality of gas intake holes.

2. The gas intake liner according to claim 1, wherein the gas intake liner is an integral structure and includes a first assembly and a plurality of first spacers located within the first assembly, the plurality of first spacers dividing a space within the first assembly to form the plurality of gas intake holes.

3. The gas intake liner according to claim 1, wherein the gas intake liner is a split structure and includes a plurality of second assemblies, the plurality of second assemblies being arranged sequentially in the first direction, with adjacent two second assemblies in contact; and
in the plurality of second assemblies:
each of the plurality of second assemblies is configured to form one intake port; or
each of the plurality of second assemblies has at least one second spacer, such that each of the plurality of second assemblies forms at least two intake ports; or
a part of the plurality of second assemblies each form one intake port, and another part of the plurality of second assemblies each has at least one second spacer, such that a corresponding second assembly forms at least two intake ports.

4. The gas intake liner according to claim 3, wherein two second assemblies located at opposite side edges of the gas intake liner each has the second spacer, forming two intake ports respectively serving as an auxiliary gas intake hole and a process gas intake hole, the process gas intake hole being located at inner side of the auxiliary gas intake hole, and a dimension of the auxiliary gas intake hole in the first direction being smaller than a dimension of the process gas intake hole in the first direction.

5. The gas intake liner according to claim 1, wherein:
the gas intake liner has a flat structure having a top flat wall and a bottom flat wall, both of the top flat wall and the bottom flat wall are parallel to the through direction and the first direction, respectively;
the gas intake liner has two arc-shaped sidewalls respectively forming two opposing side edges of the gas intake liner; the two arc-shaped sidewalls are arranged opposite each other and protrude in a direction away from each other; and
the two arc-shaped sidewalls are connected between the top flat wall and the bottom flat wall.

6. The gas intake liner according to claim 1, wherein the plurality of gas intake holes are all flat holes, a dimension of each of the plurality of gas intake holes in the first direction is larger than a dimension each of the plurality of gas intake holes in a second direction, and the second direction is perpendicular to both the through direction and the first direction.

7. The gas intake liner according to claim 1, wherein, among the plurality of gas intake holes, two of the plurality of gas intake holes adjacent to the two opposing side edges of the gas intake liner are two auxiliary gas intake holes, and other of the plurality of gas intake holes located between the two auxiliary gas intake holes are process gas intake holes.

8. The gas intake liner according to claim 7, wherein a dimension of a process gas intake hole in the first direction is larger than a dimension of an auxiliary gas intake hole in the first direction.

9. The gas intake liner according to claim 7, wherein a gas intake width formed by the plurality of gas intake holes in the first direction is a first gas intake width, and a gas intake width formed by the two auxiliary gas intake holes in the first direction is a second intake width, and a ratio of the second intake width to the first intake width is 1:25 to 1:10.

10. The gas intake liner according to claim 7, wherein the gas intake liner is applied in the vapor deposition process chamber, the vapor deposition process chamber including a chamber and a carrier disposed within the chamber, the two auxiliary gas intake holes being facing towards an inner side of an edge of the carrier, or the two auxiliary gas intake holes being opposite to an outer side of the edge of the carrier.

11. A process chamber comprising a chamber and the gas intake liner according to claim 1, the process chamber having a process space, the gas intake liner being disposed in a side wall of the chamber, and the plurality of gas intake holes communicating with the process space.

12. The process chamber according to claim 11, further comprising:
a carrier disposed within the chamber;
wherein:
the gas intake liner has a split structure and includes a plurality of second assemblies, the plurality of second assemblies being arranged sequentially in the first direction, with adjacent two second assemblies in contact;
two of the plurality of second assemblies located at opposite side edges of the gas intake liner each is provided with a second separator to form two gas intake holes, respectively serving as an auxiliary gas intake hole and a process gas intake hole, the process gas intake hole being located at inner side of the auxiliary gas intake hole;
the auxiliary gas intake hole is facing towards an inner side of an edge of the carrier; or
the auxiliary gas intake hole corresponds to an outer side of the edge of the carrier.

13. The process chamber according to claim 11, wherein:
the gas intake liner is detachably installed in the chamber; or
a corrosion resistance of the gas intake liner is higher than a corrosion resistance of the chamber.

14. A vapor deposition process chamber comprising:
a chamber, an inner liner disposed within the chamber, and the gas intake liner according to claim 1.

15. The vapor deposition process chamber according to claim 14, further comprising:
a carrier located within the chamber, the chamber including a top cover, the top cover at least forming a top wall of the chamber located above the inner liner, the top wall of the chamber being located above the carrier and protruding towards the carrier.
